(19) United States
(12) Patent Application Publication
(10) Pub. No.: US 2026/0247713 A1
(43) Pub. Date: Aug. 20, 2026

(54) ARRAY SUBSTRATE, DISPLAY PANEL AND DISPLAY APPARATUS

(71) Applicants: Beijing BOE Technology Development Co., Ltd., Beijing (CN); BOE Technology Group Co., Ltd., Beijing (CN)

(72) Inventors: Jian ZHANG, Beijing (CN); Wei YAN, Beijing (CN); Xue HE, Beijing (CN); Zhen WANG, Beijing (CN); Jian SUN, Beijing (CN); Haidong SU, Beijing (CN); Huijie ZHANG, Beijing (CN); Yadong ZHANG, Beijing (CN); Wenwen QIN, Beijing (CN); Han ZHANG, Beijing (CN); Yue SHAN, Beijing (CN); Deshuai WANG, Beijing (CN); Lu HAN, Beijing (CN); Kun YANG, Beijing (CN)

(21) Appl. No.: 18/995,027

(22) PCT Filed: Aug. 30, 2023
(86) PCT No.: PCT/CN2023/115924

§ 371 Date: Jan. 15, 2025

(51) Int. Cl. H10D 86/40; G02F 1/1362; H10D 86/60

(52) U.S. Cl. CPC H10D 86/441; G02F 1/13629; G02F 1/136295; H10D 86/60

(57) ABSTRACT

Embodiments of the disclosure provide an array substrate, a display panel and a display apparatus. The array substrate includes: a plurality of first metal wires extending in the first direction, a plurality of conductive portions in the display region; an orthographic projection of at least one conductive portion is between the orthographic projections of adjacent first metal wires on the base substrate; the second conductive layer includes: a plurality of first electrodes in the display region; a first metal sub-wire and a second metal sub-wire included in the first metal wire are on two sides adjacent to the conductive portion; the first metal sub-wire is electrically connected with the second portion; the first part is electrically connected with the first electrode through the conductive portion.

### CROSS-REFERENCE TO RELATED APPLICATIONS

The present application is a National Stage of International Application No. PCT/CN2023/115924, filed Aug. 30, 2023, the entire contents of which are incorporated by reference in the present application.

### TECHNICAL FIELD

The present disclosure relates to the field of semiconductor technology, in particular to an array substrate, a display panel and a display apparatus.

### BACKGROUND

Virtual reality technology is a new technology that “seamlessly” integrates real-world information and virtual world information. Compared with conventional display products, the most obvious feature of virtual reality display products is that they have ultra-high resolution. At present, the best choice for ultra-high pixel per inch (PPI) is the liquid crystal display (LCD) technology, because in the LCD display structure, the pixel circuit has only one switching transistor (Thin Film Transistor, TFT) which is very conducive to achieving high PPI.

### SUMMARY

An embodiment of the present disclosure provides an array substrate, a display panel and a display apparatus. The array substrate includes a display region and a non-display region located at a periphery of the display region, and further includes: a base substrate; a first active layer located on a side of the base substrate and including a plurality of first active patterns in the display region; wherein each first active pattern includes: a first portion extending in a first direction, and a second portion extending from one end of the first portion; a first metal layer including: a plurality of first metal wires extending in the first direction; wherein an orthographic projection of the first portion on the base substrate is located between orthographic projections of adjacent first metal wires on the base substrate, and a part of an orthographic projection of the second portion on the base substrate overlaps a part of an orthographic projection of the first metal wire on the base substrate; a first conductive layer including a plurality of conductive portions located in the display region; wherein an orthographic projection of at least one of the conductive portions on the base substrate is located between the orthographic projections of adjacent first metal wires on the base substrate; and a second conductive layer including a plurality of first electrodes located in the display region; a first metal sub-wire and a second metal sub-wire comprised in the first metal wire are on two sides adjacent to the conductive portion; wherein the first metal sub-wire is electrically connected with the second portion; the first portion is electrically connected with the first electrode through the conductive portion; a distance between an orthographic projection of the conductive portion on the base substrate and an orthographic projection of the first metal sub-wire on the base substrate is greater than a distance between the orthographic projection of the conductive portion on the base substrate and an orthographic projection of the second metal sub-wire on the base substrate.

In a possible implementation, the conductive portion, the first metal sub-wire and the second metal sub-wire satisfy a following relation: 15%≤b/a≤75%, wherein a represents a minimum distance between the orthographic projection of the conductive portion on the base substrate and the orthographic projection of the first metal sub-wire on the base substrate, and b represents a minimum distance between the orthographic projection of the conductive portion on the base substrate and the orthographic projection of the second metal sub-wire on the base substrate.

In a possible implementation, the conductive portion, the first metal sub-wire and the second metal sub-wire satisfy a following relation: 3%≤(a−b)/c≤15%, where c represents a minimum distance between the first metal sub-wire and the second metal sub-wire adjacent to the first metal sub-wire.

In a possible implementation, the conductive portion, the first metal sub-wire and the second metal sub-wire satisfy a following relation: 60%≤d/c≤95%, wherein d represents a length of the conductive portion in a direction perpendicular to the first direction.

In a possible implementation, the first portion includes a first symmetry axis extending in the first direction, and the conductive portion includes a second symmetry axis extending in the first direction; and the second symmetry axis is located on a side, away from the first metal sub-wire, of the first symmetry axis.

In a possible implementation, the first electrode includes a first outer edge extending in the first direction; between two adjacent first metal wires, a part of an orthographic projection of the first outer edge on the base substrate is located on a side, away from the first metal sub-wire, of the orthographic projection of the first portion on the base substrate; the conductive portion includes a second outer edge extending in the first direction; between two adjacent first metal wires, a part of an orthographic projection of the second outer edge on the base substrate is located on a side, away from the first metal sub-wire, of the orthographic projection of the first portion on the base substrate; and between two adjacent first metal wires, a part of the orthographic projection of the second outer edge on the base substrate is located on a side, away from the first metal sub-wire, of the first outer edge.

In a possible implementation, the first electrode includes a third outer edge extending in the first direction; between two adjacent first metal wires, a part of an orthographic projection of the third outer edge on the base substrate is located on a side, close to the first metal sub-wire, of the orthographic projection of the first portion on the base substrate; the conductive portion includes a fourth outer edge extending in the first direction; between two adjacent first metal wires, a part of an orthographic projection of the fourth outer edge on the base substrate is located on a side, close to the first metal sub-wire, of the orthographic projection of the first portion on the base substrate; and between two adjacent first metal wires, a part of the orthographic projection of the third outer edge on the base substrate is located on a side, away from the first metal sub-wire, of orthographic projection of the fourth outer edge on the base substrate.

In a possible implementation, the first electrode includes a third outer edge extending in the first direction; between two adjacent first metal wires, a part of an orthographic projection of the third outer edge on the base substrate is located on a side, close to the first metal sub-wire, of the orthographic projection of the first portion on the base substrate; the conductive portion includes a fourth outer edge extending in the first direction; between two adjacent first metal wires, a part of an orthographic projection of the fourth outer edge on the base substrate is located on a side, close to the first metal sub-wire, of the orthographic projection of the first portion on the base substrate; and between the two adjacent first metal wires, a part of the orthographic projection of the third outer edge on the base substrate coincides with a part of the orthographic projection of the fourth outer edge on the base substrate.

In a possible implementation, the array substrate further includes a second metal layer located between the first active layer and the first conductive layer, and the second metal layer includes a plurality of second metal wires extending in the second direction; the first portion includes: a first sub-portion, a second sub-portion, and a third sub-portion that are sequentially distributed along the first direction; wherein an orthographic projection of the second sub-portion on the base substrate overlaps the orthographic projection of the second metal wire on the base substrate; the first sub-portion is located on a side, facing the second portion, of the second sub-portion, and the third sub-portion is located on a side, away from the second portion, of the second sub-portion; and an orthographic projection of the first sub-portion on the base substrate and the orthographic projection of the conductive portion on base the substrate have an overlapping region.

In a possible implementation, the array substrate further includes: a second metal layer located between the first active layer and the first conductive layer, and the second metal layer includes a plurality of second metal wires extending in the second direction; the second portion includes: a fourth sub-portion connected with the first portion and extending in a third direction, and a fifth sub-portion connected with the fourth sub-portion; the first metal wire is electrically connected with the fifth sub-portion; the second direction intersects with the first direction, and the third direction intersects with the first direction; each conductive portion includes: a fifth outer edge extending in the second direction and facing the fifth sub-portion; and the orthographic projection of the second metal wire on the base substrate covers an orthographic projection of the fifth outer edge on the base substrate.

In a possible implementation, a distance between the orthographic projection of thee sixth outer edge on the base substrate and the orthographic projection of the fifth outer edge on the base substrate in the first direction is one-fifth to four-fifths of a length of the orthographic projection of the second metal wire in the first direction on the base substrate.

In a possible implementation, the second metal wire includes a sixth outer edge extending in the second direction and facing the fifth sub-portion; an orthographic projection of the sixth outer edge on the base substrate is located on a side, facing the orthographic projection of the fifth sub-portion on the base substrate, of the orthographic projection of the fifth outer edge on the base substrate.

In a possible implementation, the first conductive layer is located on a side, away from the base substrate, of the first active layer; the array substrate further includes: a first insulating layer located between the first active layer and the first conductive layer, and a first through hole penetrating through the first insulating layer, wherein each conductive portion is electrically connected with the first portion through the first through hole; between two adjacent first metal wires, a minimum distance between a center of an orthographic projection of the first through hole on the base substrate and the orthographic projection of the first metal sub-wire on the base substrate is greater than a minimum distance between the center of the orthographic projection of the first through hole on the base substrate and the orthographic projection of the second metal sub-wire on the base substrate.

In a possible implementation, the first electrode is located on a side, away from the base substrate, of the first conductive layer; the array substrate further includes: a second insulating layer located between the first conductive layer and the first electrode, and a second through hole penetrating through the second insulating layer; the first electrode is electrically connected with the conductive portion through the second through hole; and between two adjacent first metal wires, a minimum distance between a center of an orthographic projection of the second through hole on the base substrate and the orthographic projection of the first metal sub-wire on the base substrate is greater than a minimum distance between the center of the orthographic projection of the second through hole on the base substrate and the orthographic projection of the second metal sub-wire on the base substrate.

In a possible implementation, at least a part of the orthographic projection of the first through hole on the base substrate does not overlap at least a part of the orthographic projection of the second through hole on the base substrate.

In a possible implementation, the first insulating layer includes one or a combination of following: a first gate insulating layer; a first interlayer dielectric layer; or a second interlayer dielectric layer.

In a possible implementation, a thickness of at least one of the first gate insulating layer, the first interlayer dielectric layer and the second interlayer dielectric layer is greater than 3000 Å.

In a possible implementation, the array substrate further includes: a third metal layer located on a side, facing the base substrate, of the first active layer; the third metal layer includes: a plurality of third metal wires extending in the second direction, and an orthographic projection of the third metal wire on the base substrate covers the orthographic projection of the second metal wire on the base substrate.

In a possible implementation, the array substrate further includes: a plurality of pixel light transmitting regions, and each pixel light transmitting regions includes: a plurality of pixel light transmitting region rows extending in the first direction and arranged in the second direction; at least one of the pixel light transmitting region rows includes: a first pixel light transmitting region, a second pixel light transmitting region, and a third pixel light transmitting region; a waveband range of emergent light of the third pixel light transmitting region is smaller than a waveband range of emergent light of the first pixel light transmitting region, and smaller than a waveband range of emergent light of the second pixel light transmitting region; and the third metal wire includes: a third metal wire main portion extending in the second direction, and a first shading structure connected to the third metal wire main portion; a maximum length of the first shading structure in the first direction is greater than a maximum length of the third metal wire main portion in the first direction; an orthographic projection of the first shading structure on the base substrate is located in a gap between orthographic projections of at least two partially adjacent third pixel light transmitting regions in the first direction on the base substrate.

In a possible implementation, the array substrate further includes: a spacer; and the orthographic projection of the first shading structure on the base substrate covers an orthographic projection of the spacer on the base substrate.

In a possible implementation, the third metal wire further includes: a second shading structure connected to the third metal wire main portion; a maximum length of the second shading structure in the first direction is greater than the maximum length of the third metal wire main portion in the first direction, and is less than the maximum length of the first shading structure in the first direction; and the orthographic projection of the second shading structure on the base substrate is located in a gap between orthographic projections of two partially adjacent third pixel light transmitting regions on the base substrate in the second direction, and the orthographic projection of the second shading structure on the base substrate does not overlap the orthographic projection of the first shading structure on the base substrate.

In a possible implementation, the array substrate further includes a second active layer located on a side, facing the base substrate, of the first active layer, a drive source-drain located on a side, away from the base substrate, of the second active layer, and a drive gate, which are all in the non-display region.

In a possible implementation, a material of the first active layer includes: metal oxide; a material of the second active layer includes: low-temperature poly silicon.

In a possible implementation, the second active layer is located between the third metal layer and the base substrate; the drive gate is in the third metal layer; the drive source-drain is in the first metal layer.

In a possible implementation, the second active layer is located between the third metal layer and the first active layer; the drive source-drain is in the second metal layer; the drive gate is in the third metal layer.

In a possible implementation, the array substrate further includes: a third conductive layer on a side, away from the base substrate, of the second conductive layer, the third conductive layer includes a plurality of hollows, and a part of an orthographic projection of the hollow on the base substrate overlaps a part of the orthographic projection of the first electrode on the base substrate.

In a possible implementation, the array substrate further includes: a fourth metal layer on a side, facing the base substrate, of the third conductive layer and in contact with the third conductive layer; the fourth metal layer includes: a fourth metal wire extending in the first direction, and an orthographic projection of the fourth metal wire on the base substrate covers the orthographic projection of the first metal wire on the base substrate.

An embodiment of the present disclosure further provides a display panel, including the array substrate of aforementioned embodiments and an opposing substrate arranged opposite to the array substrate.

An embodiment of the present disclosure further provides a display apparatus, including the display panel of aforementioned embodiment.

### BRIEF DESCRIPTION OF FIGURES

FIG. 1A is a first schematic diagram of a display panel where a crosstalk defect occurs.

FIG. 1B is a second schematic diagram of a display panel where a crosstalk defect occurs.

FIG. 1C is a third schematic diagram of a display panel where a crosstalk defect occurs.

FIG. 1D is a fourth schematic diagram of a display panel where a crosstalk defect occurs.

FIG. 2A is a first top view of an array substrate provided by an embodiment of the present disclosure.

FIG. 2B is a single-layer schematic diagram of a third metal layer in FIG. 2A.

FIG. 2C is a single-layer schematic diagram of a first active layer in FIG. 2A.

FIG. 2D is a single-layer schematic diagram of a second metal layer in FIG. 2A.

FIG. 2E is a single-layer schematic diagram of a first metal layer in FIG. 2A.

FIG. 2F is a single-layer schematic diagram of a first conductive layer in FIG. 2A.

FIG. 2G is a single-layer schematic diagram of a second conductive layer in FIG. 2A.

FIG. 3 is a cross-sectional schematic diagram along a dotted line A1A2 in FIG. 2A.

FIG. 4A is a first schematic diagram of only a part of layers in FIG. 2A.

FIG. 4B is a second schematic diagram of only a part of layers in FIG. 2A.

FIG. 5A is a schematic diagram of a self-pixel electrode and associated structure provided by an embodiment of the present disclosure.

FIG. 5B is a schematic diagram of a first metal wire M11 and associated structure provided by an embodiment of the present disclosure.

FIG. 5C is a schematic diagram of adjacent pixel electrodes and associated structures provided by an embodiment of the present disclosure.

FIG. 5D is a schematic diagram of a structure of a first coupling capacitance C_{dp1} corresponding to FIG. 5A.

FIG. 5E is a schematic diagram of a structure of a second coupling capacitance C_{dp2} corresponding to FIG. 5A.

FIG. 6 is a second top view of an array substrate provided by an embodiment of the present disclosure.

FIG. 7A is a third top view of an array substrate provided by an embodiment of the present disclosure.

FIG. 7B is a schematic diagram of a structure of a first coupling capacitance C_{dp1} corresponding to FIG. 7A.

FIG. 7C is a schematic diagram of a structure of a second coupling capacitance C_{dp2} corresponding to FIG. 7B.

FIG. 8 is a schematic diagram of stacked layers of only a part of layers in FIG. 7A.

FIG. 9 is a fourth top view of an array substrate provided by an embodiment of the present disclosure.

FIG. 10A is a fifth top view of an array substrate provided by an embodiment of the present disclosure.

FIG. 10B is a signal-layer schematic diagram of a third metal wire M31 in FIG. 10A.

FIG. 10C is a schematic diagram of a larger region of FIG. 10B.

FIG. 11 is a first section view of an array substrate provided by an embodiment of the present disclosure.

FIG. 12 is a second section view of an array substrate provided by an embodiment of the present disclosure.

FIG. 13A is a sixth top view of an array substrate provided by an embodiment of the present disclosure.

FIG. 13B is a single-layer schematic diagram of a third conductive layer in FIG. 13A.

FIG. 13C is a schematic diagram of a larger region of FIG. 13B.

FIG. 14 is a structural schematic diagram of a display panel provided by an embodiment of the present disclosure.

### DETAILED DESCRIPTION

Different forms to implement. A person of ordinary skill in the art to which he belongs can easily understand the fact that the means and contents may be transformed into one or more forms without departing from the purpose and scope of the present disclosure. Therefore, this disclosure should not be construed as confined to the contents described in the following embodiments. Without conflict, the embodiments in the present disclosure and the features in the embodiments may be arbitrarily combined with each other.

In the drawings, the size, thickness or region of the layers of one or more constituent elements are sometimes exaggerated for clarity. Therefore, one of the methods of the present disclosure is not necessarily limited to that size, and the shape and size of the parts in the drawings do not reflect the true proportions. In addition, the drawings illustrate ideal examples, and one of the ways in which this disclosure is made is not limited to the shapes or numerical values shown in the drawings.

Ordinal numbers such as “first”, “second” and “third” in this specification are set to avoid confusion of constituent elements, and are not intended to be quantitatively qualified. The word “multiple” or “a plurality of” in the present disclosure may include two or more quantities.

In this description, for convenience, the use of words and phrases indicating orientations or positional relationships, such as “middle”, “up”, “down”, “front”, “rear”, “vertical”, “horizontal”, “top”, “bottom”, “inside”, “outside”, etc., to illustrate the positional relationships of the constituent elements with reference to the accompanying drawings, is only for the convenience of describing this description and simplifying the description, and does not indicate or imply that the device or element referred to must have a specific orientation, be constructed and operated in a particular orientation, and therefore cannot be construed as limiting the present disclosure. The positional relationships of the constituent elements change appropriately according to the direction in which the constituent elements are described. Therefore, it is not limited to the words and phrases stated in the manual, and can be replaced appropriately according to the situation.

In this specification, unless otherwise expressly specified or limited, the terms “mounted”, “connecting” and “connected” shall be construed broadly. For example, it can be a fixed connection, or a detachable connection, or a one-piece connection; it can be mechanically connected, or electrically connected; it can be directly connected, indirectly connected by middleware, or connected within two components. For those of ordinary skill in the art, the meaning of the above terms in the present disclosure may be understood as appropriate.

For the purposes of this manual, “electrical connection” includes a situation in which the constituent elements are connected together by elements that have some electrical effect. There are no special restrictions on “elements with a certain electrical function” as long as they can transmit electrical signals between the constituent elements of the connection. Examples of “components with some electrical function” include not only electrodes and wiring, but also switching elements such as transistors, resistors, inductors, capacitors, and other components with one or more functions.

For the purposes of this manual, a transistor is a component that includes at least three terminals: a gate electrode (gate), a drain electrode, and a source electrode. The transistor has a channel region between the drain electrode (drain terminal, drain region, or drain) and the source electrode (source terminal, source region, or source), and the current can flow through the drain electrode, channel region, and source electrode. For the purposes of the present disclosure, a channel region refers to the region through which the current flows primarily.

In addition, the gate of a transistor can be called a control electrode. In the case of the use of transistors of opposite polarity, or in the case of changes in the direction of the current during circuit operation, the functions of the “source electrode” and “drain electrode” may be reversed. Therefore, in this manual, the “source electrode” and “drain electrode” can be interchanged.

For the purposes of this manual, “parallel” refers to a state in which two straight lines form an angle which is more than −10° and less than 10°, so it can include a state in which the angle is more than −5° and less than 5°. In addition, “perpendicular” refers to the state in which the angle formed by two straight lines is more than 80° and less than 100°, so it can include an angle which is more than 85° and less than 95°.

In this manual, triangles, rectangles, trapezoids, pentagons or hexagons are not strictly sense, they can be approximate triangles, rectangles, trapezoids, pentagons or hexagons, etc., and there can be some small deformations caused by tolerances, and there can be guide angles, arc edges and deformations.

In this manual, “film” and “layer” can be interchangeable. For example, you can sometimes replace “conductive layer” with “conductive film”. In the same way, it is sometimes possible to replace “insulating film” with “insulating layer”.

The terms “approximately” and “substantially” in this manual refer to the situation that the boundaries are not strictly defined, and the process and measurement errors are allowed. In this manual, “substantially the same” can refer to cases where the values differ by less than 10%.

Virtual reality (VR) headsets and augmented reality (AR) headsets use the low temperature polycrystalline oxide (LTPO) technology. The LTPO technology integrates two TFTs: low temperature poly-silicon (LTPS) and oxide TFTs. Specifically, the oxide TFT is used in the display region, and the LTPS TFT is used in the surrounding non-display region.

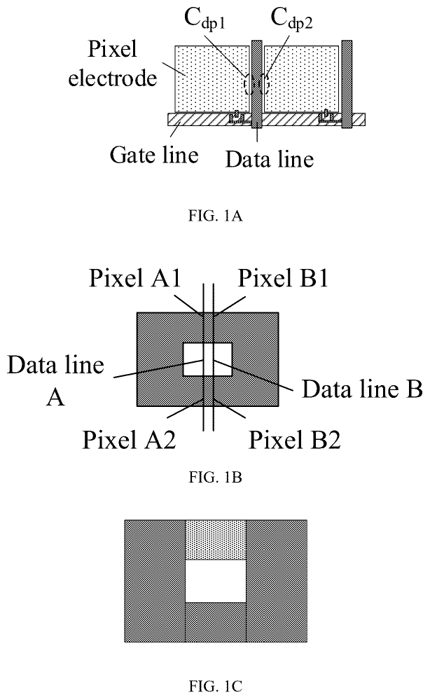

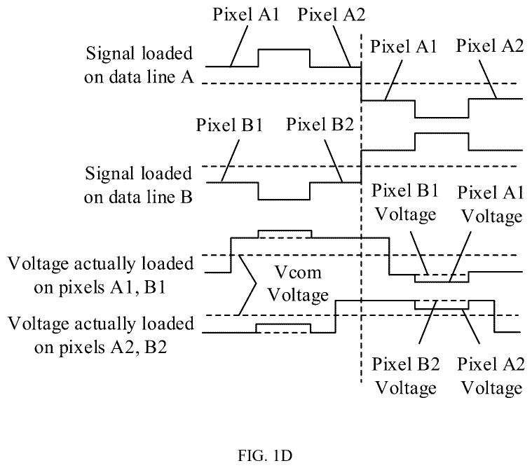

In the AR and VR display panel, as shown in FIG. 1A, there are a first coupling capacitance C_{dp1} between the data line and the self-pixel electrode (the self-pixel electrode can be understood as the pixel electrode electrically connected to the data line), and a second coupling capacitance C_{dp2} between the data line and the adjacent pixel electrode (the pixel electrode not electrically connected to the data line). When C_{dp1}>C_{dp2}, the conventional crosstalk occurs. For example, when the image with white in the middle and black at the edges shown in FIG. 1B is displayed, the image will be bounded by the middle, with the top bright and the bottom dark, as shown in FIG. 1C. Specifically, as shown in FIG. 1B, FIG. 1C and FIG. 1D, the pixel A1 and pixel A2 are two pixels at different positions on the same one data line, the pixel B1 and pixel B2 are two pixels at different positions on the same one data line, the pixel B1 and A1 are two pixels of the same row on adjacent data lines, and the pixel B2 and A2 are two pixels of the same row on adjacent data lines. When the coupling effect of the pixel itself (the first coupling capacitance C_{dp1}) and the mutual coupling effect (the second coupling capacitance C_{dp2}) are inconsistent, the charging voltage of pixel A1 is the positive voltage of L127, which will be pulled up by the voltage of L255 in the middle of the image, causing that the voltage difference between the pixel A1 and the common electrode voltage (Vcom) increases and the display is bright. The charging voltage of pixel A2 is also the negative voltage of the earlier frame, which will be pulled up by the voltage of L255 in the middle of the image, causing that the voltage difference between pixel A2 and the common electrode voltage (Vcom) decreases and the display is dark, that is, the undesirable phenomenon of the top bright and the bottom dark on the crosstalk image appears.

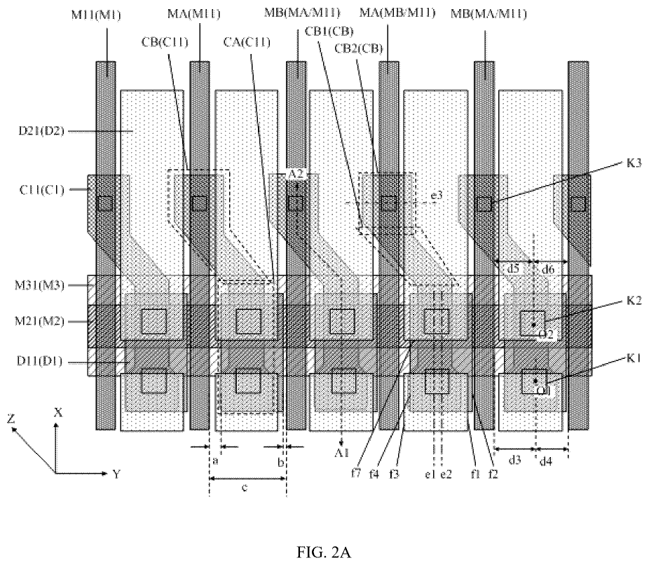

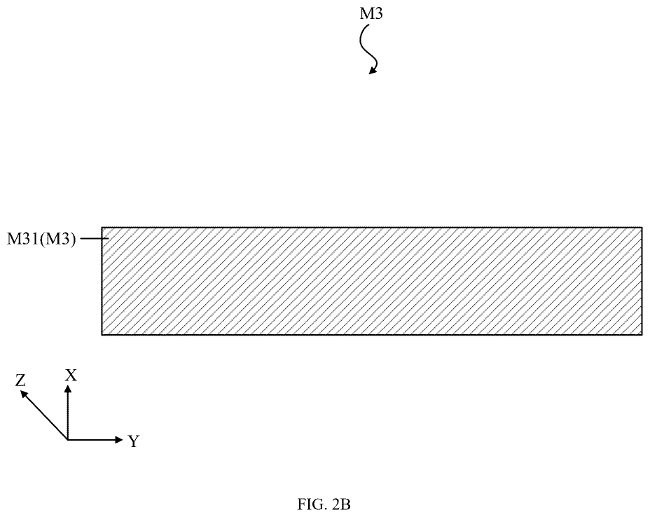

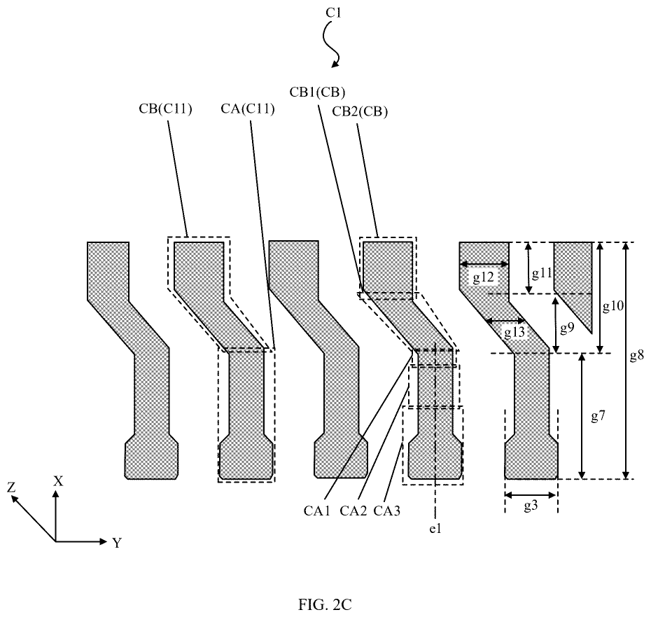

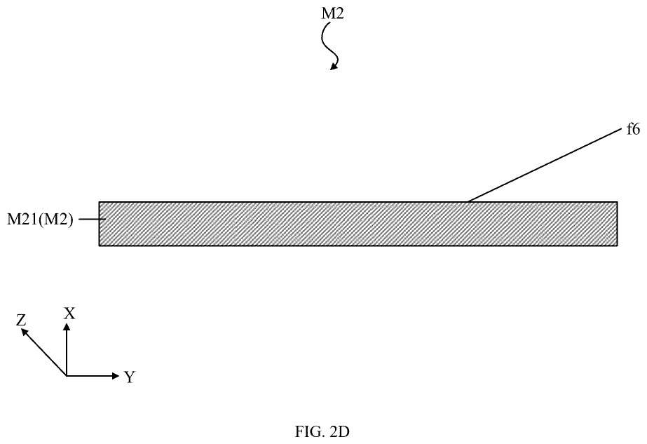

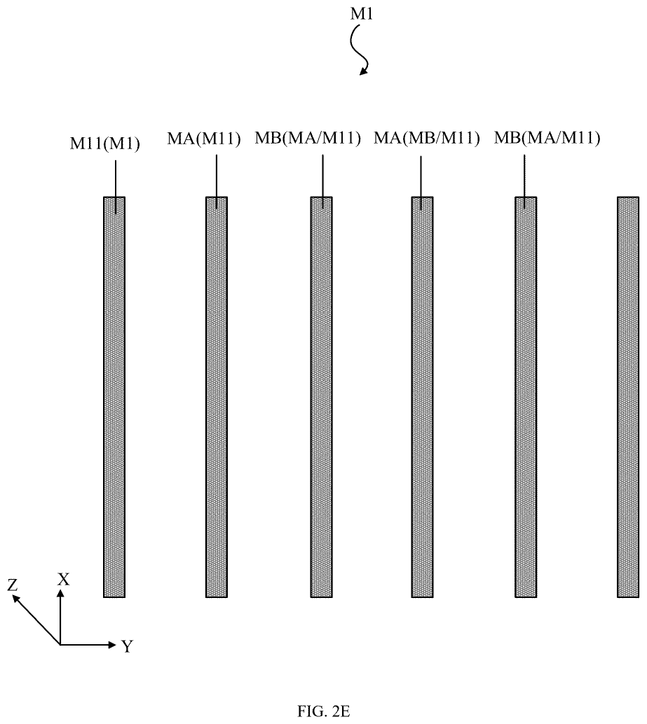

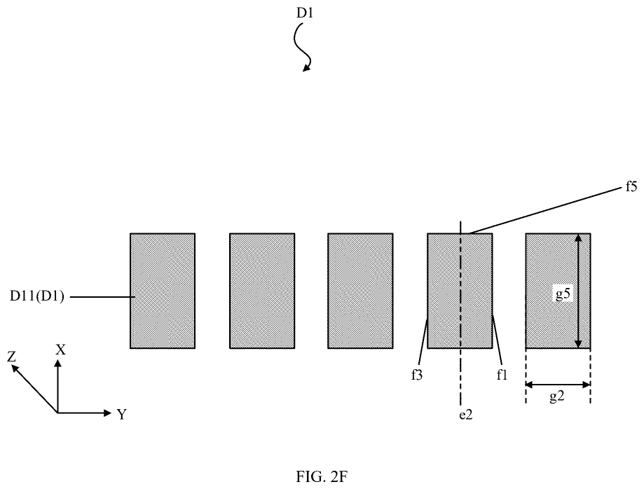

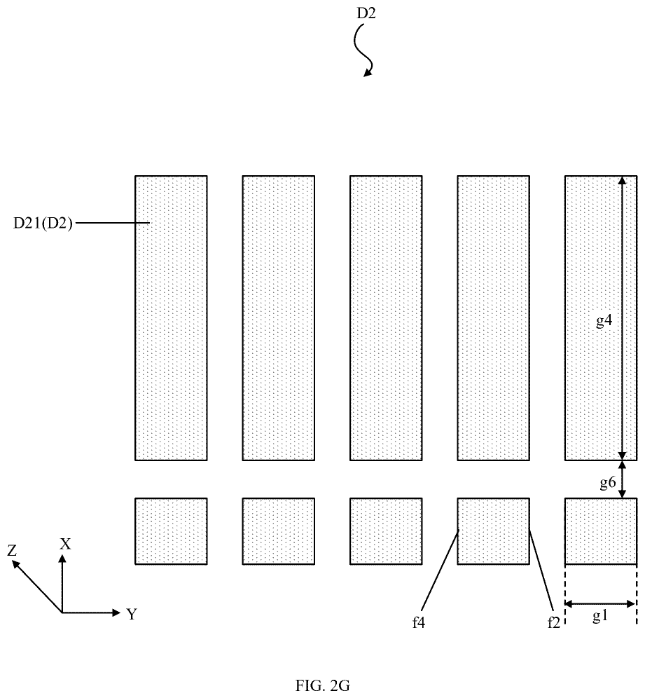

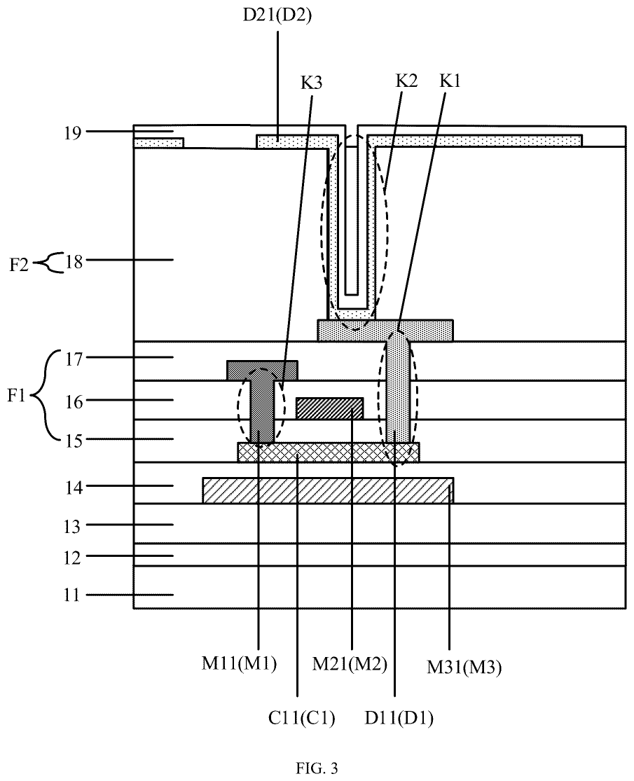

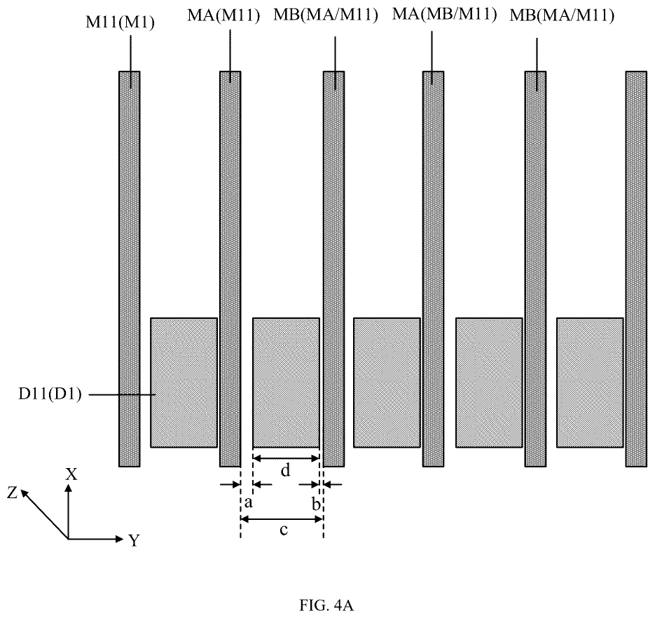

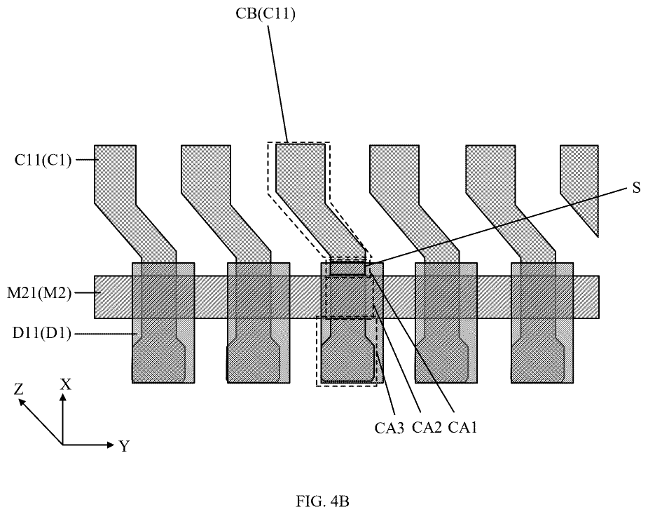

In view of this, as shown in FIG. 2A-FIG. 2G, FIG. 3 and FIG. 4A, FIG. 2B is a single-layer schematic diagram of the third metal layer in FIG. 2A, FIG. 2C is a single-layer schematic diagram of the first active layer in FIG. 2A, FIG. 2D is a single-layer schematic diagram of the second metal layer in FIG. 2A, FIG. 2E is a single-layer schematic diagram of the first metal layer in FIG. 2A, FIG. 2F is a single-layer schematic diagram of the first conductive layer in FIG. 2A, FIG. 2G is a single-layer schematic diagram of the second conductive layer in FIG. 2A, FIG. 3 is a schematic diagram of the cross-sectional schematic diagram along the dotted line A1A2 in FIG. 2A, and FIG. 4A is a schematic diagram of only a part of layers in FIG. 2A. An embodiment of the present disclosure provides an array substrate with a display region AA and a non-display region BB positioned at a periphery of the display region AA, including a base substrate 11, a first active layer C1, a first metal layer M1, a first conductive layer D1 and a second conductive layer D2. The first active layer Cl is located on one side of the base substrate 11 and includes: a plurality of first active patterns C11 located at display region AA; each first active pattern C11 includes: a first portion CA extending along the first direction X, and a second portion CB extending from one end of the first portion CA. The first metal layer M1 includes: a plurality of first metal wires M11 extending along the first direction X; the orthographic projection of the first portion CA on the base substrate 11 is located between the orthographic projections of the adjacent first metal wires M11 on the base substrate, and a part of the orthographic projection of the second portion CB on the base substrate 11 overlaps a part of the orthographic projection of the first metal wire M11 on the base substrate 11. Specifically, the first metal wire M11 may be a data line. Specifically, the display region AA may have a plurality of first transistors. The position, overlapping the first metal wire M11, of the second portion CB may be used as the first electrode of the first transistor. The position, overlapping the first metal wire M11, of the second portion CB may be conducted to realize the electrical connection between the first transistor and the data line. The first conductive layer D1 includes: a plurality of conductive portions D11 located at display region AA; the orthographic projection of at least one of the conductive portions D11 on the base substrate 11 is located between the orthographic projections of the adjacent first metal wires M11 on the base substrate 1. Specifically, the first conductive layer D1 may be a transparent conductive layer. The conductive portion D11 may be used as the second electrode of the first transistor, and connect the first active pattern C11 with the first electrode D21. Specifically, the orthographic projection of each conductive portion D11 on the base substrate 11 may be rectangular in shape, and the length of each conductive portion D11 in the first direction X may be greater than the length of each conductive portion D11 in the second direction Y. Specifically, the length of each conductive portion D11 in the first direction X may also be equal to the length of each conductive portion D11 in the second direction Y. The second conductive layer D2 includes: a plurality of first electrodes D21 located at display region AA. Specifically, the second conductive layer D2 may be a transparent conductive layer, and the material of the second conductive layer D2 may be the same as that of the first conductive layer D1. Specifically, each first electrode D21 may be a pixel electrode. Specifically, the orthographic projection of each first electrode D21 on the base substrate 11 may be located between the orthographic projections of the adjacent first metal wires M11 on the base substrate 11. Specifically, the orthographic projection of each first electrode D21 on the base substrate 11 may be rectangular in shape. The length of each first electrode D21 in the first direction X is greater than the length of each first electrode D21 in the second direction Y.

The first metal sub-wire MA, and the second metal sub-wire MB comprised in the first metal wire M11 are on two side adjacent to the conductive portion D11. The first metal sub-wire MA is electrically connected with the second portion CB, that is, the first metal wire M11 electrically connected with the second portion CB may be used as the first metal sub-wire MA.

The first portion CA is electrically connected with the first electrode D21 through the conductive portion D11. The distance a between the orthographic projection of the conductive portion D11 on the base substrate 11 and the orthographic projection of the first metal sub-wire MA on the base substrate 11 is greater than the distance b between the orthographic projection of the conductive portion D11 on the base substrate 11 and the orthographic projection of the second metal sub-wire MB on the base substrate 11.

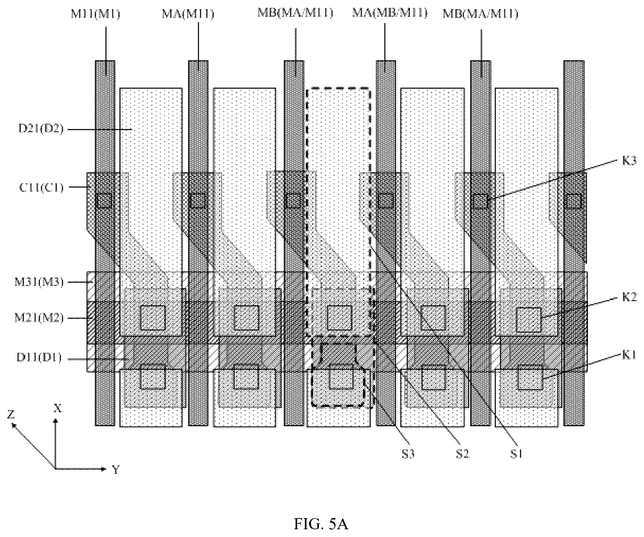

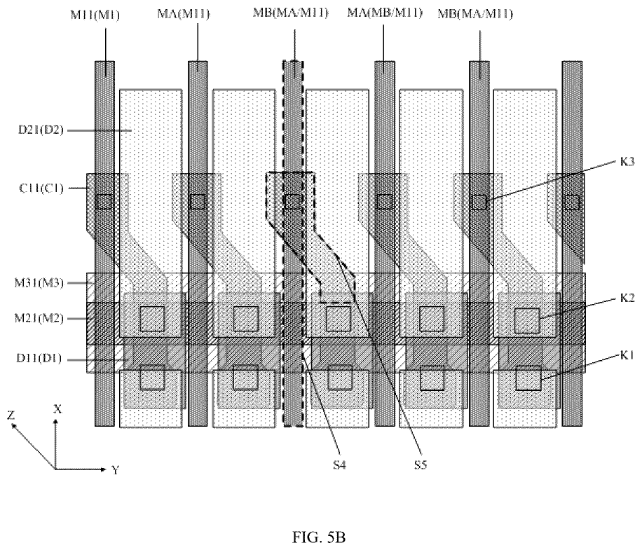

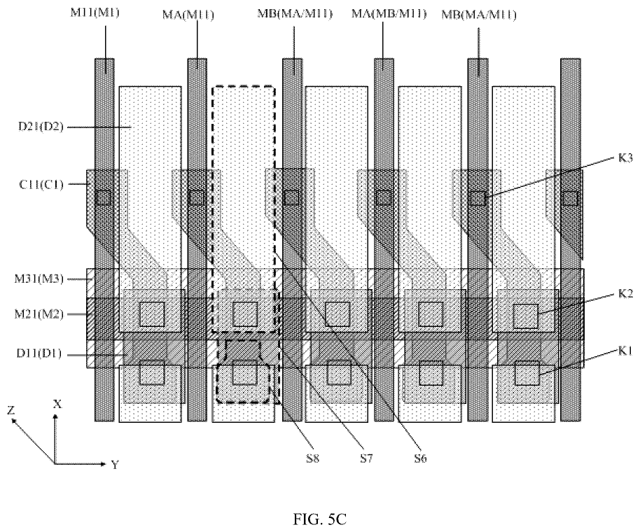

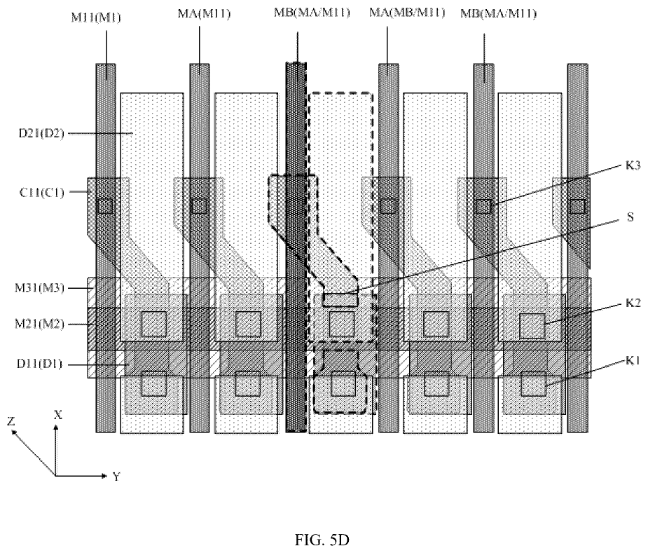

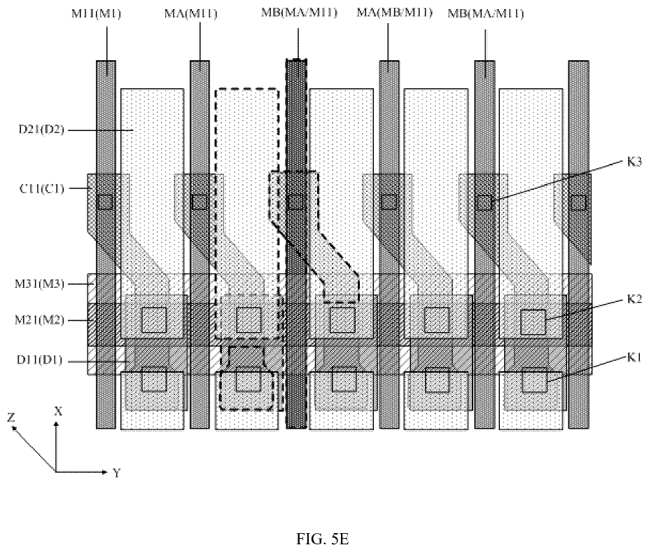

The first metal wire M11 and associated structure thereof, together with corresponding pixel electrode and associated structure thereof, may form the first coupling capacitance C_{dp1}. The first metal wire M11 and associated structure thereof, and the adjacent pixel electrodes and associated structures thereof, may form the second coupling capacitance C_{dp2}. The pixel electrode and the associated structure of the first metal wire M11 can be shown in the region shown in the dotted line frame in FIG. 5A, which may include: the first electrode D21 (as shown in the dotted line frame S1 in FIG. 5A), and the conductive portion D11 to which the first electrode D21 is connected through the second through hole K2 (as shown in the dotted line frame S2 in FIG. 5A), and a part, located on the side of the second metal wire M21 away from the side of the second metal wire M21 in the first direction X, of the first active pattern C11 to which the conductive portion D11 is connected through the first through hole K1, that is, (as shown in the dotted line frame S3 in FIG. 5A, i.e., the part of the first active pattern C11 located on the lower side of the second metal wire M21. Because the time for each row of pixels to open is very short during the time of one display frame, and it can be considered that the gate of the first transistor in the pixel is closed most of the time, the part of the first active pattern C11 covered by the second metal wire M21 may be considered as an insulator). The first metal wire M11 and the associated structure thereof may be shown in the region shown in the dotted line frame in FIG. 5B, and may include: the first metal wire M11 (as shown in the dotted line frame S4 in FIG. 5B), and a part, located on the side of the second metal wire M21 close to the second metal wire M21 in the first direction X, of the first active pattern C11 to which the conductive portion D11 is connected through the first through hole K1 (as shown in the dotted line frame S5 in FIG. 5B, i.e., the part of the first active pattern C11 located on the upper side of the second metal wire M21). The adjacent pixel electrodes and the associated structure thereof may be shown in the region shown in the dotted line frame in FIG. 5C, and may include: adjacent first electrode D21 (as shown in the dotted line frame S6 in FIG. 5C), and adjacent conductive portions D11 connected by adjacent first electrode D21 through the second through hole K2 (as shown in dotted line frame S7 in FIG. 5C), and a part, located on the side of the second metal wire M21 away from the side of the second metal wire M21 in the first direction X, of the first active pattern C11 to which the adjacent conductive portion D11 is connected through the first through hole K1 (as shown in the dotted line frame S8 in FIG. 5C, that is, a part of the first active pattern C11 that is located on the lower side of the second metal wire M21). The composition of the first coupling capacitance C_{dp1} may be shown in FIG. 5D, and the composition of the second coupling capacitance C_{dp2} may be shown in FIG. 5E.

After the research of the inventor of the present disclosure, the main reason for the difference between the first coupling capacitance C_{dp1} and the second coupling capacitance C_{dp2} is that the design of the first active pattern C11 is asymmetrical, and because the film layer between the first active layer C1 and the first conductive layer D1 is thinner, and the first active pattern C11 overlaps up and down with the conductive portion D11 in the composition of the first coupling capacitance C_{dp1} (as shown in the region of the thick solid line frame S in FIG. 5D), the forward capacitance is larger, and there is no overlap in the composition of the second coupling capacitance C_{dp2}, and then constitutes the main portion of the difference between the first coupling capacitance C_{dp1} and the second coupling capacitance C_{dp2} (in addition, although the overlapping area between the first active pattern C11 and the first electrode D21 in the first coupling capacitance C_{dp1} is larger than the overlapping area between the first active pattern C11 and the conductive portion D11, the overlapping capacitance is very small and the difference is negligible because there is a thicker layer between the first active pattern C11 and the first electrode D21). Since there is only one layer between the first metal wire M11 and the conductive portion D11, the lateral capacitance formed by the first metal wire M11 and the conductive portion D11 dominates the second coupling capacitance C_{dp2}.

In the embodiment of the present disclosure, the distance a between the orthographic projection of the conductive portion D11 on the base substrate 11 and the orthographic projection of the first metal sub-wire MA on the base substrate 11 is greater than the distance b between the orthographic projection the conductive portion D11 on the base substrate 11 and the orthographic projection of the second metal sub-wire MB on the base substrate 11. The lateral capacitance between the first metal wire M11 and the conductive portion D11 may be increased, so as to increase the second coupling capacitance C_{dp2}. Because the overlapping capacitance of the first active pattern C11 and the conductive portion D11 (as shown in the region of the thick solid line frame S in FIG. 5D) dominates the first coupling capacitance C_{dp1}, and the distance between the conductive portion D11 and the second metal sub-wire MB decreases, which does not have a great impact on the first coupling capacitance C_{dp1}, thereby reducing the difference between the second coupling capacitance C_{dp2} and the first coupling capacitance C_{dp1}, and improving the vertical crosstalk defect.

It should be noted that when the outer edge of the orthographic projection of the conductive portion D11 on the base substrate 11 is linear, the distance a between the orthographic projection of the conductive portion D11 on the base substrate 11 and the orthographic projection of the first metal sub-wire MA on the base substrate 11 may be the minimum distance a between the orthographic projection of the conductive portion D11 on the base substrate 11 and the orthographic projection of the first metal sub-wire MA on the base substrate 11. When the outer edge of the orthographic projection of the conductive portion D11 on the base substrate 11 is non-linear (for example, there is some unevenness at the edge due to the process) or when the orthographic projection of the conductive portion D11 on base the substrate 11 is non-rectangular, the distance a between the orthographic projection of the conductive portion D11 on the base substrate 11 and the orthographic projection of the first metal sub-wire MA on the base substrate 11 may be the average of distances between orthographic projections of the conductive portions D11 on the base substrate 11, and the orthographic projections of the first metal sub-wires MA on the base substrate 11. Similarly, when the outer edge of the orthographic projection of the conductive portion D11 on the base substrate 11 is linear, the distance b between the orthographic projection of the conductive portion D11 on the base substrate 11 and the orthographic projection of the second metal sub-wire MB on the base substrate 11 may be the minimum distance b between the orthographic projection of the conductive portion D11 on the base substrate 11 and the orthographic projection of the second metal sub-wire MB on the base substrate 11. When the outer edge of the orthographic projection of the conductive portion D11 on the base substrate 11 is non-linear (for example, there is some unevenness at the edge due to the process) or when the orthographic projection of the conductive portion D11 on the base substrate 11 is non-rectangular, the distance b between the orthographic projection of the conductive portion D11 on the base substrate 11 and the orthographic projection of the second metal sub-wire MB on the base substrate 11 may be the average of distances between the orthographic projections of the conductive portions D11 on the base substrate 11 and the orthographic projections of the second metal sub-wires MB on the substrate 11.

It should be noted that the first metal sub-wire MA is electrically connected to the second portion CB, which may be understood as the first metal sub-wire MA is electrically connected to the second portion CB through the first transistor. When the orthographic projection of the conductive portion D11 on the base substrate 11 is rectangular in shape, the minimum distance a between the orthographic projection of the conductive portion D11 on the base substrate 11 and the orthographic projection of the first metal sub-wire MA on the base substrate 11 may be the distance between the left edge of the conductive portion D11 and the right edge of the first metal sub-wire MA. The minimum distance b between the orthographic projection of the conductive portion D11 on the base substrate 11 and the orthographic projection of the second metal sub-wire MB on the base substrate 11 may be the distance between the right edge of the conductive portion D11 and the left edge of the second metal sub-wire MB.

In one possible embodiment, combined with the FIG. 2A or FIG. 4A, the conductive portion D11, the first metal sub-wire MA, and the second metal sub-wire MB satisfy the following relation: 15%≤b/a≤75%, a represents the minimum distance between the orthographic projection of the conductive portion D11 on the base substrate 11 and the orthographic projection of the first metal sub-wire MA on the base substrate 11, and b represents the minimum distance b between the orthographic projection of the conductive portion D11 on the base substrate 11 and the orthographic projection of the second metal sub-wire MB on the base substrate 11.

In one possible embodiment, combined with FIG. 2A or FIG. 4A, the conductive portion D11, the first metal sub-wire MA, and the second metal sub-wire MB satisfy the following relation: 3%≤(a−b)/c≤15%, c represents the minimum distance between the first metal sub-wire MA and the second metal sub-wire MB adjacent thereto.

Specifically, in conjunction with FIG. 4A, the minimum distance c between the first metal sub-wire MA and the second metal sub-wire MB that are adjacent to each other may be the distance between the right edge of the first metal sub-wire MA and the left edge of the second metal sub-wire MB.

In one possible embodiment, combined with the FIG. 2A or FIG. 4A, the conductive portion D11, the first metal sub-wire MA, and the second metal sub-wire MB satisfy the following relation: 60%≤d/c≤95%, d represents the length of the conductive portion D11 in a direction perpendicular to the first direction X.

In one possible embodiment, the conductive portion D11, the first metal sub-wire MA, and the second metal sub-wire MB satisfy: 70%≤d/c≤90%. In one possible embodiment, the conductive portion D11, the first metal sub-wire MA, and the second metal sub-wire MB satisfy: 75%≤d/c≤85%. In one possible embodiment, the conductive portion D11, the first metal sub-wire MA, and the second metal sub-wire MB satisfy: 78%≤d/c≤85%. In one possible embodiment, the conductive portion D11, the first metal sub-wire MA, and the second metal sub-wire MB satisfy: d/c=78%. In one possible embodiment, the conductive portion D11, the first metal sub-wire MA, and the second metal sub-wire MB satisfy: d/c=79%. In one possible embodiment, the conductive portion D11, the first metal sub-wire MA, and the second metal sub-wire MB satisfy: d/c=79.64%; In one possible embodiment, the conductive portion D11, the first metal sub-wire MA, and the second metal sub-wire MB satisfy: d/c=80%. In one possible embodiment, the conductive portion D11, the first metal sub-wire MA, and the second metal sub-wire MB satisfy: d/c=81%.

In one possible embodiment, the minimum distance a between the orthographic projection of the conductive portion D11 on the base substrate 11 and the orthographic projection of the first metal sub-wire MA on the base substrate 11 may be in a range of 0.35 μm to 1.15 μm. The minimum distance b between the orthographic projection of the conductive portion D11 on the base substrate 11 and the orthographic projection of the second metal sub-wire MB on the base substrate 11 may be in a range of 0.05μm to 0.85μm.

In one possible embodiment, the minimum distance a between the orthographic projection of the conductive portion D11 on the base substrate 11 and the orthographic projection of the first metal sub-wire MA on the base substrate 11 may be in a range of 0.3 μm to 1.5 μm. The minimum distance b between the orthographic projection of the conductive portion D11 on the base substrate 11 and the orthographic projection of the second metal sub-wire MB on the base substrate 11 may be in a range of 0.2 μm to 1 μm.

In one possible embodiment, the minimum distance c between the first metal sub-wire MA and the second metal sub-wire MB that are adjacent to each other may be in a range of 2 μm to 10 μm. In one possible embodiment, the minimum distance c between the first metal sub-wire MA and the second metal sub-wire MB that are adjacent to each other may be in a range of 4 μm to 8 μm. In one possible embodiment, the minimum distance c between the first metal sub-wire MA and the second metal sub-wire MB that are adjacent to each other may be in a range of 5 μm to 6 μm. In one possible embodiment, the minimum distance c between the first metal sub-wire MA and the second metal sub-wire MB that are adjacent to each other may be 5.1 μm, 5.2 μm, 5.3 μm, 5.4 μm, 5.5 μm, 5.6 μm, 5.7 μm, 5.8 μm, 5.8 μm, or 6.0 μm. In one possible embodiment, the minimum distance c between the first metal sub-wire MA and the second metal sub-wire MB that are adjacent to each other may be 5.65 μm.

In one possible embodiment, the length d of the conductive portion D11 in a direction perpendicular to the first direction X may be in a range of 2 μm to 8 μm. In one possible embodiment, the length d of the conductive portion D11 in a direction perpendicular to the first direction X may be in a range of 3 μm to 6 μm. In one possible embodiment, the length d of the conductive portion D11 in a direction perpendicular to the first direction X may be in a range of 4 μm to 5 μm. In one possible embodiment, the length d of the conductive portion D11 in a direction perpendicular to the first direction X may be 4.1 μm, 4.2 μm, 4.3 μm, 4.4 μm, 4.5 μm, 4.6 μm, 4.7 μm, 4.8 μm, 4.9 μm, or 5.0 μm.

In one possible embodiment, the length d of the conductive portion D11 in a direction perpendicular to the first direction X may be 4.5 μm, and the minimum distance c between the first metal sub-wire MA and the second metal sub-wire MB that are adjacent to each other may be 5.65 μm.

In one possible embodiment, as shown in the FIG. 2A, FIG. 2C, and FIG. 2F, the first portion CA has a first symmetry axis e1 extending along the first direction X, and the first portion CA is symmetrical with respect to the first symmetry axis e1. The conductive portion D11 has a second symmetry axis e2 extending along the first direction X, and the conductive portion D11 is symmetrical with respect to the second symmetry axis e2. The second symmetry axis e2 is located on the side, away from the first sub-metal line MA, of the first symmetry axis e1.

In one possible embodiment, as shown in the FIG. 2A, FIG. 2C, and FIG. 2F, the first electrode D21 has a first outer edge f1 extending along the first direction X; between the two adjacent first metal wires M11, a part of the orthographic projection of the first outer edge f1 on the base substrate 11 is located on a side, away from the first metal sub-wire MA, of the orthographic projection of the first portion CA on the base substrate 11. Specifically, as shown in FIG. 2F, the first outer edge f1 may be the right edge of the first electrode D21. The conductive portion D11 has a second outer edge f2 extending along the first direction X; between the adjacent two first metal wires M11, a part of the orthographic projection of the second outer edge f2 on the base substrate 11 is located on a side, away from the first metal sub-wire MA, of the orthographic projection of the first portion CA on the base substrate 11. Specifically, as shown in FIG. 2G, the second outer edge f2 may be the right edge of the conductive portion D11. Between the two adjacent first metal wires M11, a part of the orthographic projection of the second outer edge f2 on the base substrate 11 is located on a side of the first outer edge f1 away from the first metal sub-wire MA.

In one possible embodiment, as shown in FIG. 2A, FIG. 2F, and FIG. 2G, the first electrode D21 has a third outer edge f3 extending along the first direction X; between the adjacent two first metal wires M11, a part of the orthographic projection of the third outer edge f3 on the base substrate 11 is located on a side, close to the first metal sub-wire MA, of the orthographic projection of the first portion CA on the base substrate 11. Specifically, as shown in FIG. 2F, the third outer edge f3 may be the left edge of the first electrode D21. The conductive portion D11 has a fourth outer edge f4 extending along the first direction X; between the two adjacent first metal wires M11, a part of the orthographic projection of the fourth outer edge f4 on the base substrate 11 is located on a side, close to the first metal sub-wire MA, of the orthographic projection of the first portion CA on the base substrate 11. Specifically, as shown in FIG. 2G, the fourth outer edge f4 may be the left edge of the conductive portion D11. Between the two adjacent first metal wires M11, a part of the orthographic projection of the fourth outer edge f4 on the base substrate 11 is located on a side, away from the first metal sub-wire MA, of the third outer edge f3 on the base substrate 11. In the embodiment of the present disclosure, the conductive portion D11 is moved to the side away from the first metal sub-wire MA, so as to increase the second coupling capacitance C_{dp2} and reduce the difference between the second coupling capacitance C_{dp2} and the first coupling capacitance C_{dp1}, so that the vertical crosstalk defect is improved.

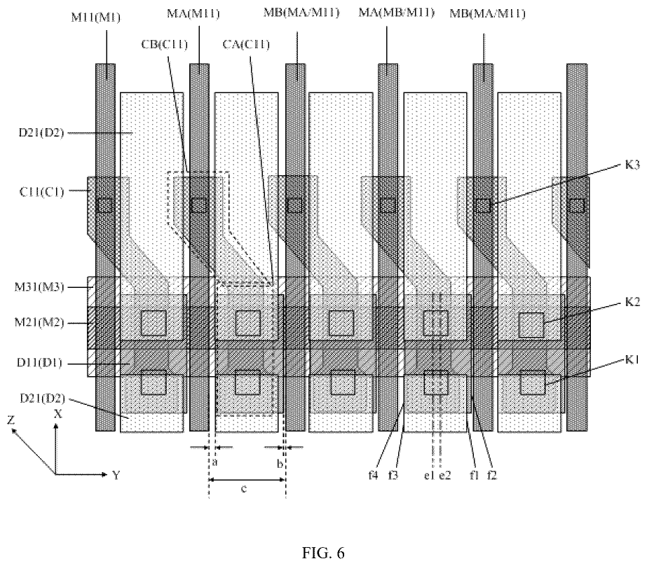

In the specific embodiment, as shown in FIG. 2A, the second coupling capacitance C_{dp2} can be increased by moving the conductive portion D11 to the side away from the first metal sub-wire MA. In another possible embodiment, as shown in FIG. 6, it is also possible not to move the conductive portion D11, but to move the edge, away from the first metal sub-wire MA, of the conductive portion D11 to the side away from the first metal sub-wire MA, that is, to increase the width of the conductive portion D11 in the second direction Y, to reduce the minimum distance b between the orthographic projection of the conductive portion D11 on the base substrate 11 and the orthographic projection of the second metal sub-wire MB on the base substrate 11, which may also increase the second coupling capacitance C_{dp2}.

Specifically, as shown in FIG. 6, the first electrode D21 has a third outer edge f3 extending along the first direction X; between the adjacent two first metal wires M11, a part of the orthographic projection of the third outer edge f3 on the base substrate 11 is located on a side, close to the first metal sub-wire MA, of the orthographic projection of the first portion CA on the base substrate 11. Specifically, as shown in FIG. 6, the third outer edge f3 may be the left edge of the first electrode D21. The conductive portion D11 has a fourth outer edge f4 extending along the first direction X; between the two adjacent first metal wires M11, a part of the orthographic projection of the fourth outer edge f4 on the base substrate 11 is located on a side, close to the first metal sub-wire MA, of the orthographic projection of the first portion CA on the base substrate 11. Specifically, as shown in FIG. 6, the fourth outer edge f4 may be the left edge of the conductive portion D11; between the two adjacent first metal wires M11, a part of the orthographic projection of the third outer edge f3 on the base substrate 11 coincides with a part of the orthographic projection of the fourth outer edge f4 on the base substrate 11. In the embodiment of the present disclosure, the edge away from the first metal sub-wire MA, of the conductive portion D11 is moved to a side away from the first metal sub-wire MA, so as to increase the second coupling capacitance C_{dp2} and reduce the difference between the second coupling capacitance C_{dp2} and the first coupling capacitance C_{dp1}, thereby improving the vertical crosstalk defect.

It should be noted that, in order to clearly illustrate the position relationship of each structure of the present embodiment, FIG. 2A-FIG. 9 is to label and illustrate the edges of the first electrode D21 and the conductive portion D11, the first active pattern C11, the first metal sub-wire MA, the second metal sub-wire MB and position relationships thereof in the second row. In the specific implementation, the first electrode D21 on each row and the conductive portion D11, the first active pattern C11, the first metal sub-wire MA, the second metal sub-wire MB corresponding to the current row also satisfies the relevant edge and position relationship, and the embodiment of the present disclosure is not limited to this.

In addition, it should be noted that, for example, the first D21 in the second row from top to bottom in FIG. 2G is only shown as a part of the first electrode D21 due to the limitation of the scope of the figure, and the complete pattern of the first electrode D21 may be shown as the first electrode D21 in the first row from top to bottom, and the embodiment of the present disclosure is not limited to this.

In one possible embodiment, as shown in FIG. 2C and FIG. 4B, the array substrate further includes: a second metal layer M2 located between the first active layer C1 and the first conductive layer D1, and the second metal layer M2 includes: a plurality of second metal wires M21 extending along the second direction Y.

The first portion CA includes: the first sub-portion CA1, the second sub-portion CA2, and the third sub-portion CA3 distributed sequentially along the first direction X. The orthographic projection of the second sub-portion CA2 on the base substrate overlaps the orthographic projection of the second metal wire M21 on the base substrate 11. The first sub-portion CA1 is located on a side, facing the second portion CB, of the second sub-portion CA2, and the third sub-portion CA3 is located on a side, away from the second portion CB, of the second sub-portion CA2. That is, the part of the first portion CA that overlaps the orthographic projection of the second metal wire M21 is taken as the second sub-portion CA2.

The orthographic projection of the first sub-portion CA1 on the base substrate 11 and the orthographic projection of the conductive portion D11 on the base substrate 11 have an overlapping region. Specifically, the orthographic projection of the first sub-portion CA1 on the base substrate 11 and the orthographic projection of the conductive portion D11 on the base substrate 11 have an overlapping region, which can be shown in the thick solid line frame S in FIG. 4B.

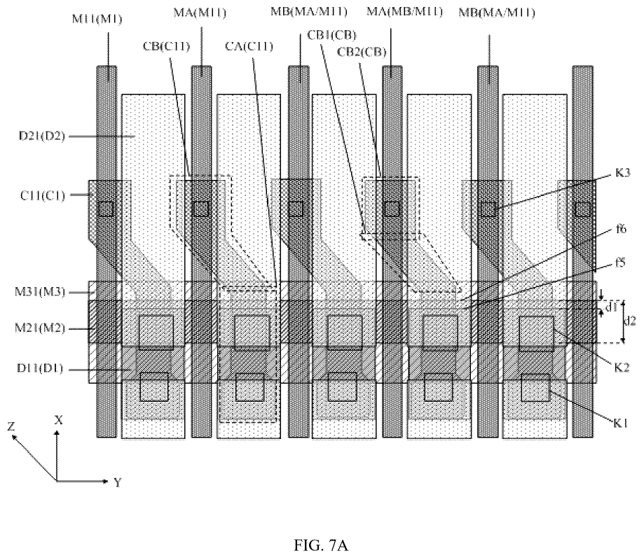

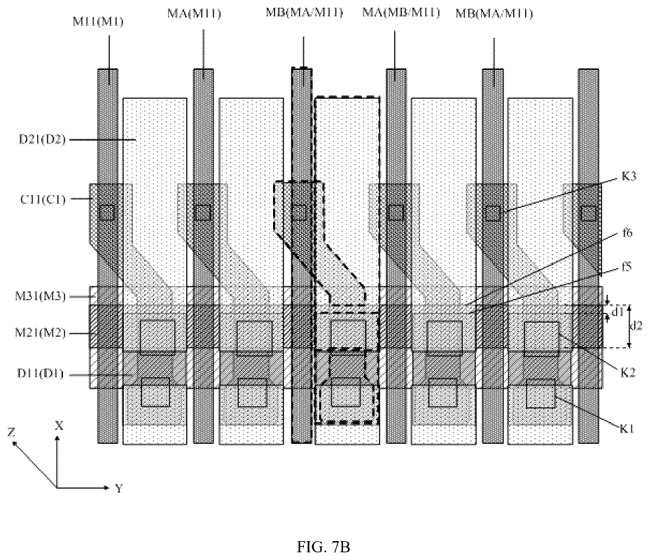

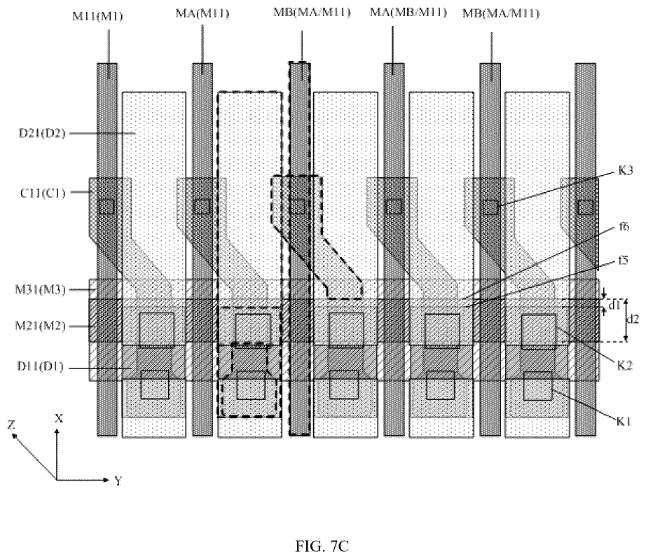

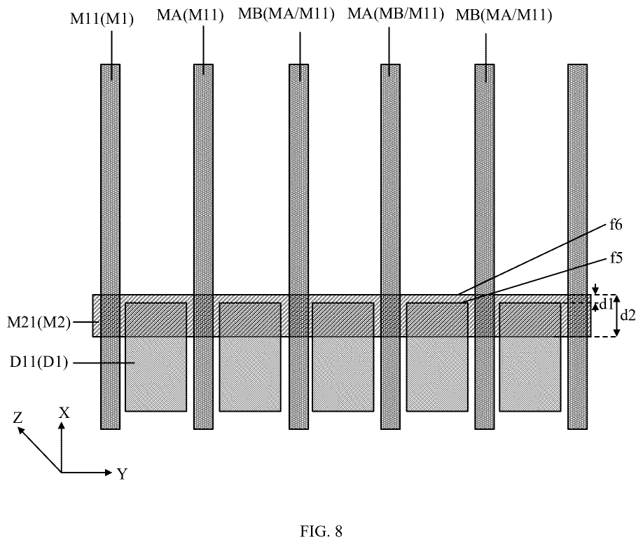

In a possible embodiment, as shown in FIG. 2A, FIG. 3, FIG. 7A and FIG. 8, FIG. 8 is a schematic diagram of stack layers of a part of layers in FIG. 7A, the array substrate further includes: a second metal layer M2 positioned between the first active layer C1 and the first conductive layer D1, and the second metal layer M2 includes: a plurality of second metal wires M21 extending along the second direction Y. The second portion CB includes: a fourth sub-portion CB1 connected with the first portion CA and extending along the third direction, a fifth sub-portion CB2 connected with the fourth sub-portion CB1. The first metal wire M11 is electrically connected with the fifth sub-portion CB2. The second direction Y intersects the first direction X, and the third direction Z intersects the first direction X. The conductive portion D11 includes: the fifth outer edge f5 extending along the second direction Y and towards the fifth sub-portion CB2. Specifically, as shown in FIG. 7A, the fifth outer edge f5 may be the upper edge of the conductive portion D11. The second metal wire M21 has a sixth outer edge f6 extending along the second direction Y and towards the fifth sub-portion CB2. Specifically, as shown in FIG. 7A, the sixth outer edge f6 may be the upper edge of the second metal wire M21. The orthographic projection of the sixth outer edge f6 on the base substrate 11 is located on a side, facing the orthographic projection of the fifth sub-portion CB2 on base the substrate 11, of the orthographic projection of the fifth outer edge f5 on the base substrate 11.

In the embodiment of the present disclosure, the second metal wire M21 has a sixth outer edge f6 extending along the second direction Y and towards the fifth sub-portion CB2, that is, the second metal wire M21 is moved up (after the second metal wire M21 is moved up, the composition of the first coupling capacitance C_{dp1} can be shown in FIG. 7B, and the composition of the second coupling capacitance C_{dp2} can be shown in FIG. 7C), the second metal wire M21 may shield the overlapping capacitance of the first active pattern C11 and the conductive portion D11 (i.e., the capacitance of the region shown in the thick solid line frame S in FIG. 5D), and then reduce the overlapping capacitance that accounts for a large proportion of the first coupling capacitance C_{dp1} and reduce the first coupling capacitance C_{dp1}. However, the upward movement of the second metal wire M21 has little effect on the lateral capacitance between the first metal wire M11 and the conductive portion D11 (which constitutes the main portion of the second coupling capacitance C_{dp2}), and then the difference between the second coupling capacitance C_{dp2} and the first coupling capacitance C_{dp1} can be reduced, so as to improve the vertical crosstalk defect.

Specifically, the second metal wire M21 may be a gate line.

Specifically, the second direction Y may be perpendicular to the first direction X. The angle formed by the third direction Z and the first direction X may be in a range of 0 to 90°. Specifically, the angle between the third direction Z and the first direction X may be in a range of 30° to 60°. Specifically, the angle between the third direction Z and the first direction X may be 45°.

In one possible embodiment, as shown in FIG. 2A, FIG. 2C, FIG. 2F and FIG. 2G, the length g1 along the second direction Y of the orthotic projection of the first electrode D21 on the base substrate 11 may be equal to the length g2 along the second direction Y of the orthographic projection of the conductive portion D11 on the base substrate 11. The length g1 along the second direction Y of the orthographic projection of the first electrode D21 on the base substrate 11 may be less than the minimum distance c between the first metal sub-wire MA and the second metal sub-wire MB that are adjacent to each other. In one possible embodiment, as shown in FIG. 2A, FIG. 2C, FIG. 2F, and FIG. 2G, the length g4 along the first direction X of the orthographic projection of the first electrode D21 on the base substrate 11 may be greater than the length g5 along the first direction X of the orthographic projection of the conductive portion D11. In one possible embodiment, as shown in FIG. 2A, FIG. 2C, FIG. 2F, and FIG. 2G, the length g5 along the first direction X of the orthographic projection of the conductive portion D11 on the base substrate 11 may be one-fifth to four-fifths of the length g4 along the first direction X of the orthographic projection of the first electrode D21 on the base substrate 11. In one possible embodiment, the length g5 along the first direction X of the orthographic projection of the conductive portion D11 on the base substrate 11 may be one-half of the length g4 along the first direction X of the orthographic projection of the first electrode D21 on the base substrate 11.

In one possible embodiment, as shown in FIG. 2A, the orthographic projection of the conductive portion D11 on the base substrate 11 may cover the orthographic projection of the gap between the two adjacent first electrodes D21 in the first direction X on the base substrate 11. In one possible embodiment, as shown in FIG. 2A, the overlapping area between the orthographic projection of the conductive portion D11 on the base substrate 11 and the orthographic projection of the first electrode D21 on the base substrate 11, may account for one-fifth to four-fifths of area of the orthographic projection of the conductive portion D11 on the base substrate 11. In one possible embodiment, as shown in FIG. 2A, the overlapping area between the orthographic projection of the conductive portion D11 on the base substrate 11 and the orthographic projection of the first electrode D21 on the base substrate 11 may account for one-third of area of the orthographic projection of the conductive portion D11 on the base substrate 11.

In one possible embodiment, as shown in FIG. 2A, FIG. 2C, FIG. 2F and FIG. 2G, the distance g6 between the two adjacent first electrodes D21 in the first direction X may be one-fifth to four-fifths of the length g5 in the first direction X of the orthographic projection of the conductive portion D11 on the base substrate 11. In one possible embodiment, as shown in FIG. 2A, FIG. 2C, FIG. 2F and FIG. 2G, the distance g6 between the two adjacent first electrodes D21 in the first direction X may be one-third of the length g5 in the first direction X of the orthographic projection of the conductive portion D11 on the base substrate 11.

In one possible embodiment, as shown in FIG. 2A, FIG. 2C, FIG. 2F, and FIG. 2G, the maximum length g3 in the second direction Y of the orthographic projection of the first portion CA1 of the first active pattern C11 on the base substrate 11 may be smaller than the length g2 in the second direction Y of the orthographic projection of the conductive portion D11 on the base substrate 11.

In one possible embodiment, as shown in FIG. 2C, the maximum length g7 in the first direction X of the orthographic projection of the first portion CA1 of the first active pattern C11 on the base substrate 11 may be one-third to three-thirds of the maximum length g8 in the first direction X of the orthographic projection of the first active pattern C11 on the base substrate 11. In one possible embodiment, as shown in FIG. 2C, the maximum length g7 in the first direction X of the orthographic projection of the first portion CA1 of the first active pattern C11 on the base substrate 11 may be one-half of the maximum length g8 in the first direction X of the orthographic projection of the first active pattern C11 on the base substrate 11.

In one possible embodiment, as shown in FIG. 2C, the maximum length g9 in the first direction X of the orthographic projection of the fourth sub-portion CB1 of the first active pattern C11 on the base substrate 11 may be one-third to three-thirds of the maximum length g10 in the first direction X of the orthographic projection of the second portion CB of the first active pattern C11 on the base substrate 11. In one possible embodiment, as shown in FIG. 2C, the maximum length g9 in the first direction X of the orthographic projection of the fourth sub-portion CB1 of the first active pattern C11 on the base substrate 11 may be one-half of the maximum length g10 in the first direction X of the orthographic projection of the second portion CB of the first active pattern C11 on the base substrate 11. The maximum length g11 in the first direction X of the orthographic projection of the fifth sub-portion CB2 of the first active pattern C11 on the base substrate 11 may be one-half of the maximum length g10 in the first direction X of the orthographic projection of the second portion CB of the first active pattern C11 on the base substrate 11.

In one possible embodiment, as shown in FIG. 2C, the maximum length g12 in the second direction Y of the orthographic projection of the fifth sub-portion CB2 of the first active pattern C11 on the base substrate 11 may be equal to the maximum length g3 in the second direction Y of the orthographic projection of the first portion CA of the first active pattern C11 on the base substrate 11. In one possible embodiment, as shown in FIG. 2C, the maximum length g12 in the second direction Y of the orthographic projection of the fifth sub-portion CB2 of the first active pattern C11 on the base substrate 11 may be greater than the length g13 in the second direction Y of the orthographic projection of the fourth sub-portion CB1 of the first active pattern C11 on the base substrate 11.

In one possible embodiment, as shown in FIG. 7A, and FIG. 8, the distance d1 between the orthographic projection of the sixth outer edge f6 on the base substrate 11 and the orthographic projection of the fifth outer edge f5 on the base substrate 11 in the first direction X is one-fifth to four-fifths of the length d2 of the orthographic projection of the second metal wire M21 on the base substrate 11 in the first direction X.

In one possible embodiment, as shown in FIG. 7A and FIG. 8, the orthographic projection of the second metal wire M21 on the base substrate 11 covers the orthographic projection of the fifth outer edge f5 on the base substrate 11. That is, the maximum upward movement of the second metal wire M21 does not exceed the upper edge of the conductive portion D11.

In one possible embodiment, the distance dl between the orthographic projection of the sixth outer edge f6 on the base substrate 11 and the orthographic projection of the fifth outer edge f5 on the base substrate 11 in the first direction X is in a range of 1 μm to 3 μm. In one possible embodiment, the distance d1 between the orthographic projection of the sixth outer edge f6 on the substrate 11 and the orthographic projection of the fifth outer edge f5 on the substrate 11 in the first direction X is 1.5 μm.

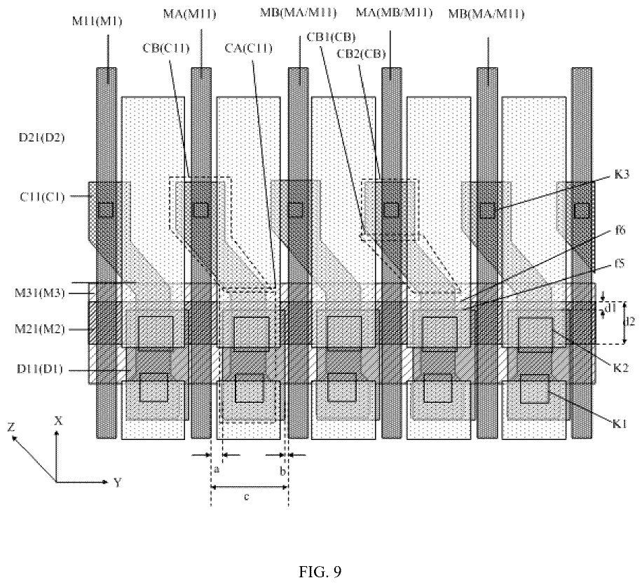

In the specific embodiment, as shown in FIG. 2A, the difference between the second coupling capacitance C_{dp2} and the first coupling capacitance C_{dp1} can be reduced only by making the minimum distance a between the orthographic projection of the conductive portion D11 on the base substrate 11 and the orthographic projection of the first metal sub-wire MA on the base substrate 11 greater than the minimum distance d between the orthographic projection of the conductive portion D11 on the base substrate 11 and the orthographic projection of the second metal sub-wire MB on the base substrate 11 (i.e., the conductive portion D11 is shifted to the right). As shown in FIG. 7A and FIG. 8, it is also possible to reduce the difference between the second coupling capacitance C_{dp2} and the first coupling capacitance C_{dp1} only by making the orthographic projection of the sixth outer edge f6 on the base substrate 11 be located a side, facing the orthographic projection of the fifth sub-portion CB2 on the base substrate 11, of the orthographic projection of the fifth outer edge f5 on the base substrate 11 (that is, moving the second metal wire M21 upward). As shown in FIG. 9, it is also possible to reduce the difference between the second coupling capacitance C_{dp2} and the first coupling capacitance C_{dp1} by making the minimum distance a between the orthographic projection of the conductive portion D11 on the base substrate 11 and the orthographic projection of the first metal sub-wire MA on the base substrate 11 greater than the minimum distance b of the orthographic projection of the conductive portion D11 on the base substrate 11 and the orthographic projection of the second metal sub-wire MB on the substrate 11 (i.e., the conductive portion D11 is shifted to the right), and at the same time, the orthographic projection of the sixth outer edge f6 on the base substrate 11 is located on a side, facing the orthographic projection of the fifth sub-portion CB2 on the base substrate 11, of the orthographic projection of the fifth outer edge f5 on the base substrate 11 (that is, the second metal wire M21 is moved up).

In one possible embodiment, as shown in FIG. 2A and FIG. 3, the first conductive layer D1 is located on a side, away from the base substrate 11, of the first active layer C1. The array substrate further includes: a first insulating layer F1 located between the first active layer Cl and the first conductive layer D1, and a first through hole K1 penetrating through the first insulating layer F1. The conductive portion D11 is electrically connected with the first portion CA through the first through hole K1. Between the two adjacent first metal wires M11, the minimum distance d3 between the center O1 of the orthographic projection of the first through hole K1 on the base substrate 11 and the orthographic projection of the first metal sub-wire MA on the base substrate 11 is greater than the minimum distance d4 between the center O1 of the orthographic projection of the first through hole K1 on the base substrate 11 and the orthographic projection of the second metal sub-wire MB on the base substrate 11. In the embodiment of the disclosure, when the conductive portion D11 is shifted to the right, the first through hole K1 connecting the conductive portion D11 and the first active pattern C11 is also shifted to the right, so as to avoid affect the conduction effect of the conductive portion D11 and the first active pattern C11 when the conductive portion D11 is shifted to the right and the first through hole K11 is not shifted to the right.

In one possible embodiment, as shown in FIG. 2A and FIG. 3, the first electrode D21 is located on the side of the first conductive layer D1 that deviates from the substrate 11; The array substrate further includes: a second insulating layer F2 located between the first conductive layer D1 and the first electrode D21, and a second through hole K2 penetrating through the second insulating layer F2. The first electrode D21 is electrically connected with the conductive portion D11 through the second through hole K2. Between the two adjacent first metal wires M11, the minimum distance d5 between the center 02 of the orthographic projection of the second through hole K2 on the base substrate 11, and the orthographic projection of the first metal sub-wire MA on the base substrate 11 is greater than the minimum distance d6 between the center 02 of the orthographic projection of the second through hole K2 on the base substrate 11, and the orthographic projection of the second metal sub-wire MB on the base substrate 11. In the embodiment of the disclosure, when the conductive portion D11 is shifted to the right, the second through hole K2 connecting the conductive first electrode D21 and the conductive portion D11 is also shifted to the right, so as to avoid the conduction effect of the first electrode D21 and the conductive portion D11 being affected when the conductive portion D11 is shifted to the right and the second through hole K2 is not shifted to the right.

In one possible embodiment, at least a part of the orthographic projection of the first through hole K1 on the base substrate 11 does not overlap at least a part of the orthographic projection the second through hole K2 on the base substrate 11. In one possible embodiment, as shown in FIG. 2A and FIG. 3, the entirety of the orthographic projection of the first through hole K1 on the base substrate 11 does not overlap the entirety of the orthographic projection of the second through hole K2 on the base substrate 11.

In one possible embodiment, the first insulating layer F1 includes one or a combination of the following: a first gate insulating layer 15; a first interlayer dielectric layer 16; or a second interlayer dielectric layer 17.

Specifically, as shown in FIG. 3, the first interlayer dielectric layer 16 may be located on a side, away from the base substrate 11, of the first gate insulating layer 15. The second interlayer dielectric layer 17 may be located on a side of away from the base substrate 11, of the first interlayer dielectric layer 16.

In one possible embodiment, as shown in FIG. 3, the first insulating layer F1 includes: a first gate insulating layer 15, a first interlayer dielectric layer 16 and a second interlayer dielectric layer 17.

In one possible embodiment, as shown in FIG. 2A and FIG. 3, the array substrate further includes: a third through hole K3 penetrating through the first interlayer dielectric layer 16 and the second interlayer dielectric layer 17. The first metal wire M11 is electrically connected to the second portion CB of the first active pattern C11 through the third through hole K3.

In one possible embodiment, as shown in FIG. 2A, the orthographic projection of the third metal wire M31 on the base substrate 11 b covers the orthographic projection of the second through hole K2 on the base substrate 11. Specifically, the orthographic projection of the second metal wire M21 on the base substrate 11 covers the orthographic projection of the second through hole K2 on the base substrate 11. In one possible embodiment, the orthographic projection of the second through hole K2 on the base substrate 11 is located at the overlapping region of the first electrode D21 and the conductive portion D11, so that the first electrode D21 and the conductive portion D11 are electrically connected at the overlapping region through the second through hole K2.

In one possible embodiment, the orthographic projection of the third metal wire M31 on the base substrate 11 covers a part of the orthographic projection of the first through hole K1 on the base substrate 11. The orthographic projection of the first metal wire M11 on the base substrate 11 covers the orthographic projection of the third through hole K3 on the base substrate 11. In one possible embodiment, the orthographic projection of the first through hole K1 on the base substrate 11 is located at the overlapping region of the orthographic projection of the first portion CA of the first active pattern C11 and the orthographic projection of the conductive portion D11 on the base substrate 11, so as to electrically connect the first portion CA and the conductive portion D11 at the overlapping region through the first through hole K1.

In one possible embodiment, the orthographic projection of the first metal wire M11 on the base substrate 11 covers the orthographic projection of the third through hole K3 on the base substrate 11. Specifically, the orthographic projection of the third through hole K3 on the base substrate 11 is located at the overlapping region of the orthographic projection of the first metal wire M11 and the orthographic projection of the second portion CB of the first active pattern C11 on the base substrate 11, so that the first metal wire M11 is electrically connected with the second portion CB of the first active pattern C11 through the third through hole K3.

In one possible embodiment, the orthographic projections of the first through hole K1 and the second through hole K2 on the base substrate 11 are all located between the orthographic projection of the first metal sub-wire MA and the orthographic projection of the second metal sub-wire MB on the base substrate 11. In one possible embodiment, the orthographic projections of the first through hole K1 and the second through hole K2 on the base substrate 11 have a gap in the first direction X. Specifically, the length of the gap between the orthographic projections of the first through hole K1 and the second through hole K2 in the first direction X may be one-quarter to three-quarters of the length of the conductive portion D11 in the first direction X.

In one possible embodiment, the third through hole K3 has a symmetry axis e3 of third through hole extending along the second direction Y. The first electrode D21 has an outer edge f7 of the first electrode extending along the second direction Y and facing one side of the electrically connected conductive portion D11. The distance between the symmetry axis e 3 of the third through hole and the outer edge f7 of the first electrode in the first direction X may be one-quarter to three-quarters of the length of the first electrode D21 in the first direction X. In one possible embodiment, the distance between the symmetry axis of the third through hole e3 and the outer edge f7 of the first electrode in the first direction X may be one-half of the length of the first electrode D21 in the first direction X, and the symmetry axis e3 of the third through hole is located at the position of half the length of the first electrode D21 in the first direction X.

In the specific embodiment, the thickness of the first insulating layer F1 between the first active layer C1 and the first conductive layer DI can be adjusted by adjusting at least one or combination of the first gate insulating layer 15, the first interlayer dielectric layer 16 or the second interlayer dielectric layer 17, and moving conductive portion D11 right and/or moving the second metal trace M21 upwards, which can achieve accurate capacitance difference control, and reduce the difference between the second coupling capacitance C_{dp2} and the first coupling capacitance C_{dp1}.

In one possible embodiment, as shown in FIG. 3, the thickness of at least one of the first gate insulating layer 15, the first interlayer dielectric layer 16, or the second interlayer dielectric layer 17 is greater than 3000 Å.

In one possible embodiment, the thickness of the first gate insulating layer 15 can be controlled to be in a range of 500 Å to 1500 Å, the thickness of the first interlayer dielectric layer 16 can be controlled to be in a range of 1500 Å to 2500 Å, and the thickness of the second interlayer dielectric layer 17 can be controlled to be in a range of 3500 Å to 4500 Å, so as to reduce the difference between the second coupling capacitance C_{dp2} and the first coupling capacitance C_{dp1}. In one possible embodiment, the thickness of the first gate insulating layer 15 can be controlled to be 1000 Å, the thickness of the first interlayer dielectric layer 16 can be controlled to be 3000 Å, and the thickness of the second interlayer dielectric layer 17 can be controlled to be 4000 Å to reduce the difference between the second coupling capacitance C_{dp2} and the first coupling capacitance C_{dp1}.

In one possible embodiment, the thickness of the first gate insulating layer 15 can be controlled to be in a range of 500 Å to 1500 Å, the thickness of the first interlayer dielectric layer 16 is in a range of 3500 Å to 4500 Å, and the thickness of the second interlayer dielectric layer 17 is in a range of 2500 Å to 3500 Å, so as to reduce the difference between the second coupling capacitance C_{dp2} and the first coupling capacitance C_{dp1}. In one possible embodiment, the thickness of the first gate insulating layer 15 can be controlled to be 1000 Å, the thickness of the first interlayer dielectric layer 16 can be controlled to be 4000 Å, and the thickness of the second interlayer dielectric layer 17 can be controlled to be 3000 Å to reduce the difference between the second coupling capacitance C_{dp2} and the first coupling capacitance C_{dp1}.

In one possible embodiment, the thickness of the first gate insulating layer 15 can be controlled to be in a range of 500 Å to 1500 Å, the thickness of the first interlayer dielectric layer 16 is in a range of 1500 Å to 2500 Å, and the thickness of the second interlayer dielectric layer 17 is in a range of 4500 Å to 5500 Å, so as to reduce the difference between the second coupling capacitance C_{dp2} and the first coupling capacitance C_{dp1}. In one possible embodiment, the thickness of the first gate insulating layer 15 can be controlled to be 1000 Å, the thickness of the first interlayer dielectric layer 16 can be controlled to be 2000 Å, and the thickness of the second interlayer dielectric layer 17 can be controlled to be 5000 Å to reduce the difference between the second coupling capacitance C_{dp2} and the first coupling capacitance C_{dp1}.

In one possible embodiment, as shown in FIG. 3, the array substrate further includes: a third metal layer M3 located on a side, facing the base substrate 11, of the first active layer C1. The third metal layer M3 includes: a plurality of third metal wires M31 extending along the second direction Y, and the orthographic projection of the third metal wire M31 on the base substrate 11 covers the orthographic projection of the second metal wire M21 on the base substrate 11. Specifically, the third metal wire M31 can be used to block at least part of the first active pattern C11 of the first transistor, so as to avoid the influence of external ambient light on the first active pattern C11 and affect the characteristics of the first transistor.

In one possible embodiment, as shown in FIG. 2A, the orthographic projection of the third metal wire M31 on the base substrate 11 may cover the orthographic projection of the gap between the two adjacent first electrodes D21 in the first direction X on the base substrate 11. In one possible embodiment, as shown in FIG. 2A, the orthographic projection of the third metal wire M31 on the base substrate 11 may cover a part of the orthographic projection of first portion CA of the first active pattern C11 on the base substrate 11 and cover a part of the orthographic projection of the fourth sub-portion CB1 of the first active pattern C11 on the base substrate 11. The orthographic projection of the third metal wire M31 on the base substrate 11 may cover a part of the orthographic projection of the conductive portion D11 on the base substrate 11.

In one possible embodiment, as shown in the FIG. 2A, the orthographic projection of the third metal wire M31 on the base substrate 11 covers the orthographic projection of the second through hole K2 on the base substrate 11. In the embodiment of the disclosure, the orthographic projection of the third metal wire M31 on the base substrate 11 covers the orthographic projection of the second through hole K2 on the base substrate 11, that is, the third metal wire M31 of the array substrate is used to cover the second through hole K2, so that the risk of light leakage from the second through hole K2 on the array substrate can be reduced.

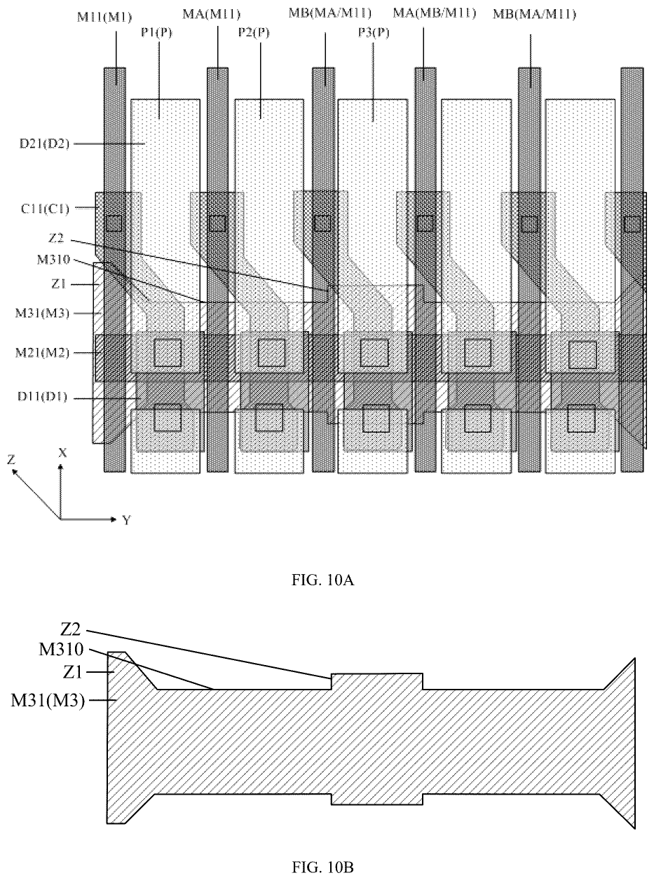

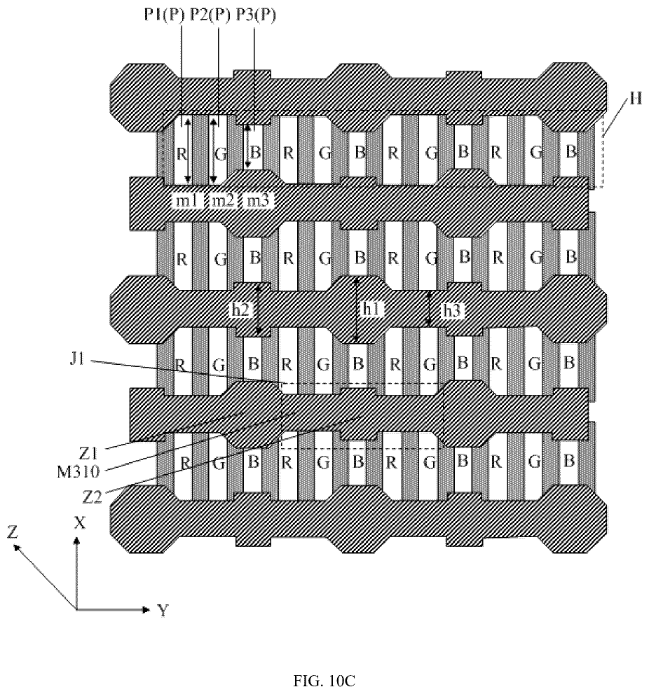

Because virtual reality technology (VR) headset products belong to near-eye display, and the image displayed on the LCD screen needs to be magnified by the imaging system many times before it can enter the human eye, even if the current VR display resolution has reached more than 1000 PPI, the screen door effect caused by the shading structure can still be seen in the whole machine display. In view of this, in one possible embodiment, as shown in FIG. 10A, FIG. 10B and FIG. 10C, FIG. 10B can be a single-layer schematic diagram of the third metal wire M31 in FIG. 10A, FIG. 10B can also be a local schematic diagram at the dotted line frame J1 in FIG. 10C, FIG. 10C can be a schematic diagram of a larger region of FIG. 10B. The array substrate includes: a plurality of pixel light transmitting regions P, each pixel light transmitting region P includes: a plurality of pixel light transmitting region rows H extending along the first direction X and arranging along the second direction Y. At least one of pixel light transmitting region rows H includes: a first pixel light transmitting region P1, a second pixel light transmitting region P2, and a third pixel light transmitting region P3. The waveband range of light emitted from the third pixel light transmitting region P3 is smaller than that of the first pixel light transmitting region P1, and smaller than that of the second pixel light transmitting region P2. Specifically, the first pixel light transmitting region P1 may be the pixel light transmitting region of red light, the second pixel light transmitting region P2 may be the pixel light transmitting region of green light, and the third pixel light transmitting region P3 may be the pixel light transmitting region of blue light. The third metal wire M31 includes: the third metal wire main portion M310 extending along the second direction Y, and the first shading structure Z1 connected to the third metal wire main portion M310. The maximum length h1 of the first shading structure Z1 in the first direction X is greater than the maximum length h3 of the third metal wire main portion M310 in the first direction X. The orthographic projection of the first shading structure Z1 on the base substrate 11 is located in the gap of between the orthographic projections of at least two partially adjacent third pixel light transmitting regions P3 on the base substrate 11 in the first direction X.

Specifically, the array substrate further includes: a spacer (not shown in the figures, the shape and position of the orthographic projection of the spacer on the base substrate 11 can be shown in FIG. 10C, that is, the orthographic projection of the spacer on the base substrate 11 can be octagonal in shape, and it can be located in a gap between the orthographic projection of least two partially adjacent third pixel light transmitting regions P3 in the first direction X on the base substrate 11). The orthographic projection of the first shading structure Z1 on the base substrate 11 covers the orthographic projection of the spacer on the base substrate 11. That is, the orthographic projection of the spacer on the base substrate 11 is located in the gap between the orthographic projections of at least two partially adjacent third pixel light transmitting regions P3 on the base substrate 11 in the first direction X.

In the embodiment of the present disclosure, the spacer is placed at the position of the gap between the adjacent blue pixel light transmitting regions, thereby effectively reducing the sensitivity of the human eye to the compensation of the shading object (such as the black matrix) at the position of the spacer (the blue pixel is lower than the green pixel and the red pixel in brightness, so placing the spacer on the gap between the adjacent blue pixel light transmitting regions brings less light-and-dark visual difference to the human eye than placing the spacer on the green pixel and the red pixel).

In a possible embodiment, as shown in FIG. 10A, FIG. 10B and FIG. 10C, the third metal wire M31 further includes: a second shading structure Z2 connected to the third metal wire main portion M310. The maximum length h2 of the second shading structure Z2 in the first direction X is greater than the maximum length h3 of the third metal wire main portion M310 in the first direction X, and is less than the maximum length h1 of the first shading structure Z1 in the first direction X. The orthographic projection of the second shading structure Z2 on the base substrate 11 is located in the gap between the orthographic projection of the two partially adjacent third pixel light transmitting regions P3 in the second direction Y on the base substrate 11, and the orthographic projection of the second shading structure Z2 on the base substrate 11 and the orthographic projection of the first shading structure Z1 on the base substrate 11 do not overlap with each other.

In the embodiment of the disclosure, the orthographic projection of the second shading structure Z2 on the base substrate 11 is located in the gap between the orthographic projection of the two partially adjacent third pixel light transmitting regions P3 in the second direction Y on the base substrate 11, and the orthographic projection of the second shading structure Z2 on the base substrate 11 and the orthographic projection of the first shading structure Z1 on the base substrate 11 do not overlap with each other, that is, the second shading structure Z2 may be arranged at a position without spacer between adjacent blue pixels, so that the brightness difference between the position of the blue pixel with spacer and the position without spacer is reduced, the brightness is more evenly distributed across the pixel region, which reduces the screen door effect and improves the visual effect.

In one possible embodiment, the length m3 of the third pixel light transmitting region P3 in the first direction X is less than the length m1 of the first pixel light transmitting region P1 in the first direction X, and less than the length m2 of the second pixel light transmitting region P2 in the first direction X.

Specifically, the pixel light transmitting region P can be understood as the effective display region of the pixel, and can be the region in the pixel region that is not blocked by the shading structure (such as the shading layer, gate line, data line, black matrix, etc.), and specifically, in a possible embodiment, as shown in FIG. 10C, the pixel light transmitting region P can be shown as a white region.

In one possible embodiment, the length m1 of the first pixel light transmitting region P1 in the first direction X is equal to the length m2 of the second pixel light transmitting region P2 in the first direction X. In the embodiment of the disclosure, the second shading structure Z2 is arranged by setting the length m3 of the third pixel light transmitting region P3 in the first direction X to be shorter, and the brightness of the third pixel light transmitting region P3 with a smaller waveband range of the emergent light is lower than that of the first pixel light transmitting region P1 and the second pixel light transmitting region P2 with a larger range of the emergent light band, so that the sensitivity of the human eye to the second shading structure Z2 can be effectively reduced, and the brightness difference between the position of spacer and the position of no spacer between the third light transmitting regions P3 of the third pixel, so that the brightness is more evenly distributed in the whole pixel region, thereby reducing the screen door effect and improving the visual effect.

In the embodiment of the present disclosure, the spacer may first be placed at the position of the gap between the adjacent blue pixel light transmitting regions, effectively reducing the sensitivity of the human eye to the compensation of the shading object (such as the black matrix) at the spacer position (the blue pixel is less bright than the green pixel and the red pixel, so placing the spacer on the gap between the adjacent blue pixel light transmitting region brings less visual difference to the human eye than on the green pixel and the red pixel). In addition, the second shading structure Z2 may be set at the position without spacer between adjacent blue pixels, which reduces the brightness difference between the position of the blue pixel with spacer and the position of the blue pixel without spacer, and makes the brightness distribution in the whole pixel region more uniform, thereby reducing the screen door effect and improving the visual effect.

In one possible embodiment, the waveband range of the emergent light of the third pixel light transmitting region P3 may also be greater than the waveband range of the emergent light of the first pixel light transmitting region P1 and greater than the waveband range of the emergent light of the second pixel light transmitting region P2. Specifically, the third pixel light transmitting region P3 can be the red pixel light transmitting region, the first pixel light transmitting region P1 can be the blue pixel light transmitting region, and the second pixel light transmitting region P2 can be the green pixel light transmitting region. That is, a second shading structure Z2 may also be arranged in the gap between at two partially adjacent red pixel light transmitting regions, and the spacer may be placed in the gap between the two adjacent red pixel light transmitting regions.

In one possible embodiment, as shown in FIG. 10C, the orthographic projections of the first shading structure Z1 and the second shading structure Z2 on the base substrate 11 are alternately distributed along the first direction X. Specifically, the first shading structure Z1 and the second shading structure Z2 may be located in the same column direction, for example, both are located in the column direction where the third pixel light transmitting region P3 is located.

In a possible embodiment, the shape of the orthographic projection shape of the first shading structure Z1 on the base substrate 11 may be the same as the shape of the orthographic projection of the spacer on the base substrate 11, for example, the orthographic projection of the spacer on the base substrate 11 may be hexagonal, octagonal, circular or elliptical in shape. The orthographic projection of the first shading structure Z1 on the base substrate 11 may also be hexagonal, octagonal, circular or elliptical in shape.

Specifically, the orthographic projection of the second shading structure Z2 on the base substrate 11 may be rectangular in shape. The maximum length of the second shading structure Z2 in the first direction X may be greater than the maximum length of the second shading structure Z2 in the second direction Y.

Specifically, the ratio of the maximum length h2 of the second shading structure Z2 in the first direction to the maximum length h1 of the first shading structure Z1 in the first direction X is greater than or equal to 0.78.

Specifically, the orthographic projection of the second shading structure Z2 on the base substrate 11 is rectangular in shape, and the maximum length h2 of the second shading structure Z2 in the first direction X may be the length of the vertical edge of the rectangle along the first direction X. The orthographic projection of the first shading structure Z1 on the base substrate 11 is octagonal in shape, and the maximum length h1 of the first shading structure Z1 in the first direction X may be the distance between the opposite two sides parallel to the second direction Y in the octagon.

In one possible embodiment, as shown in FIG. 10C, in the pixel light transmitting region row H, the first pixel light transmitting region P1, the second pixel light transmitting region P2, and the third pixel light transmitting region P3 are arranged sequentially along the second direction Y. The pixel light transmitting regions P with the same waveband range of the emergent light are located on the same one column in the first direction X, that is, the first pixel light transmitting region P1 is located in the same one column, the second pixel light transmitting region P2 is located in the same one column, and the third pixel light transmitting region P3 is located in the same one column.

In one possible embodiment, the range of the maximum length h2 of the second shading structure Z2 in the first direction X may be 8 μm to 12 μm, specifically, for example, it may be 8 μm, 9 μm, 10 μm, 10.5 μm, 11 μm, or 12 μm. The range of the maximum length h1 of the first shading structure Z1 in the first direction X may be 10 μm to 15 μm, specifically, for example, it may be 10 μm, 11 μm, 12 μm, 13 μm, 13.5 μm, 14 μm, or 15 μm. The range of the maximum length h3 of the third metal wire main portion M310 in the first direction X may be 5 μm to 10 μm, specifically, for example, it may be 5 μm, 6 μm, 7 μm, 7.5 μm, 8 μm, 9 μm, or 10 μm.

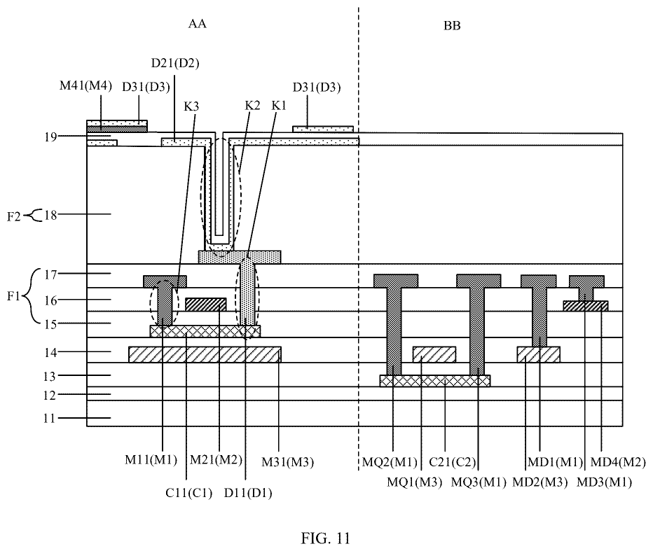

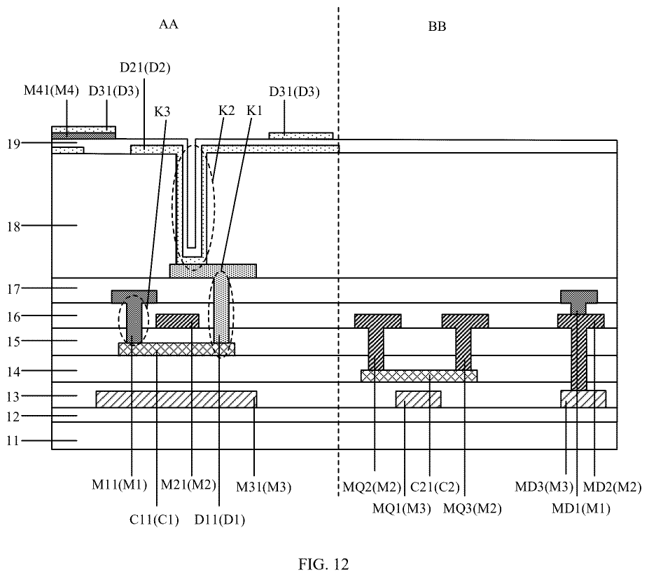

In one possible embodiment, as shown in FIG. 11 and FIG. 12, the array substrate further includes a second active layer C2 located on a side, facing the base substrate 11, of the first active layer C1 in the non-display region BB, a drive source-drain (including a drive source MQ2 and a drive drain MQ3) located on a side, away from the base substrate 11, of the second active layer C2 in the non-display region BB, and a drive gate MQ1 in the non-display region BB. Specifically, the array substrate may include a gate drive circuit in the non-display region BB. The gate driver circuit includes: a plurality of second transistors. The second transistor may include: a second active layer C2, a drive source-drain (including a drive source MQ2 and a drive drain MQ3), and a drive gate MQ1. In the embodiment of the present disclosure, the array substrate uses the low temperature polycrystalline oxide (LTPO) technology and integrates two LTPS and Oxide TFTs, which can make AR, VR products have high resolution (PPI), high aperture ratio, and high transmittance.

In one possible embodiment, as shown in FIG. 11 and FIG. 12, the array substrate further includes a first drive electrode MD1, a second drive electrode MD2, a third drive electrode MD3, and a fourth drive electrode MD4, which are located in the non-display region BB. The first drive electrode MD1 is electrically connected with the second drive electrode MD2, and the third drive electrode MD3 is electrically connected to the fourth drive electrode MD4. Specifically, the first drive electrode MD1 may be used as the first signal line, and the third drive electrode MD3 may be used as the second signal line. The first signal line may include a signal line electrically connected to the gate drive circuit, and/or a signal line electrically connected to a multiplexer. The second signal line may include a signal line electrically connected to the gate drive circuit, and/or a signal line electrically connected to a multiplexer. The first signal line may include: an initial signal line, a clock signal line, a reset signal line, or a light-emitting control line. The second signal line may include: an initial signal line, a clock signal line, a reset signal line, or a light-emitting control line.

In one possible embodiment, as shown in FIG. 11, the second active layer C2 is located between the third metal layer M3 and the base substrate 11. The drive gate MQ1 is located in the third metal layer M3. The drive source-drain (including the drive source MQ2 and the drive drain MQ3) is located in the first metal layer M1. In the embodiment of the disclosure, the drive gate MQ1 is located in the third metal layer M3. The drive source-drain is located in the first metal layer M1, which can form the corresponding drive gate MQ1 and the drive source-drain in the non-display region while forming the third metal layer M3 and the first metal layer M1 in the display region AA, thereby simplifying the production process of the display panel.

In one possible embodiment, as shown in FIG. 11, the first drive electrode MD1 and the third drive electrode MD3 may be located in the first metal layer M1. The second drive electrode MD2 may be located in the third metal layer M3, and the fourth drive electrode MD4 may be located in the second metal layer M2. Therefore, the corresponding first drive electrode MD1 and the third drive electrode MD3 in the non-display region may be formed while forming the first metal layer M1 in the display region AA; while forming the second metal layer M2 in the display region AA, the corresponding fourth drive electrode MD4 in the non-display region is formed; while forming the third metal layer M3 in the display region AA, the corresponding second drive electrode MD2 in the non-display region is formed, thereby simplifying the production process of the display panel.

In one possible embodiment, at least part of the wires of the second metal layer M2 and at least part of the wires of the third metal layer M3 may be electrically connected to each other by spanning multiple layers in the non-display region BB. For example, the second metal wire M21 and the third metal wire M31 may be electrically connected in the non-display region BB in a cross-layer manner, so as to form a double-gate structure for the transistors in the display region AA.

In one possible embodiment, as shown in FIG. 12, the second active layer C2 is located between the third metal layer M3 and the first active layer C1. The drive source-drain (including the drive source MQ2 and the drive drain MQ3) are located in the second metal layer M2. The drive gate MQ1 is located in the third metal layer M3. In the embodiment of the present disclosure, the drive source-drain is located in the second metal layer M2, the drive gate MQ1 is located in the third metal layer M3, which may form the corresponding drive gate MQ1 and the drive source-drain in the non-display region while forming the third metal layer M3 and the second metal layer M2 in the display region, thereby simplifying the production process of the display panel.

In one possible embodiment, as shown in FIG. 12, the first drive electrode MD1 may be located in the first metal layer M1. The second drive electrode MD2 may be located in the second metal layer M2, and the third drive electrode MD3 may be located in the third metal layer M3. Therefore, the corresponding first drive electrode MD1 in the non-display region can be formed while forming the first metal layer M1 in the display region AA; the corresponding second drive electrode MD2 is formed in the non-display region while forming the second metal layer M2 in the display region AA; the corresponding third drive electrode MD3 is formed in the non-display region, while forming the third metal layer M3 in the display region AA, thereby simplifying the production process of the display panel.

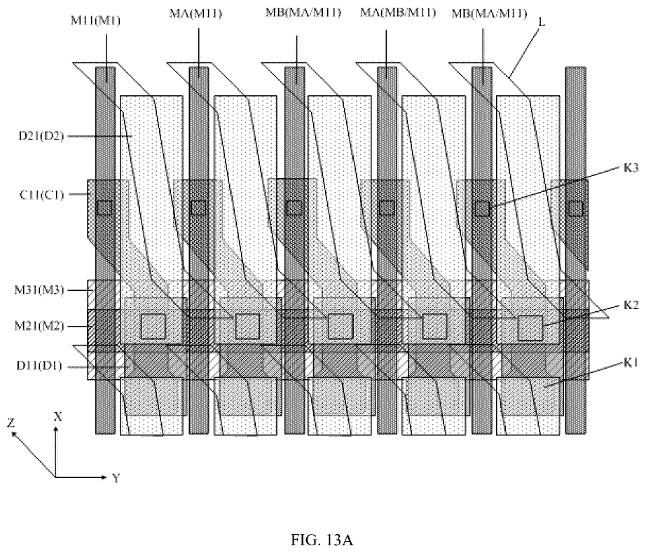

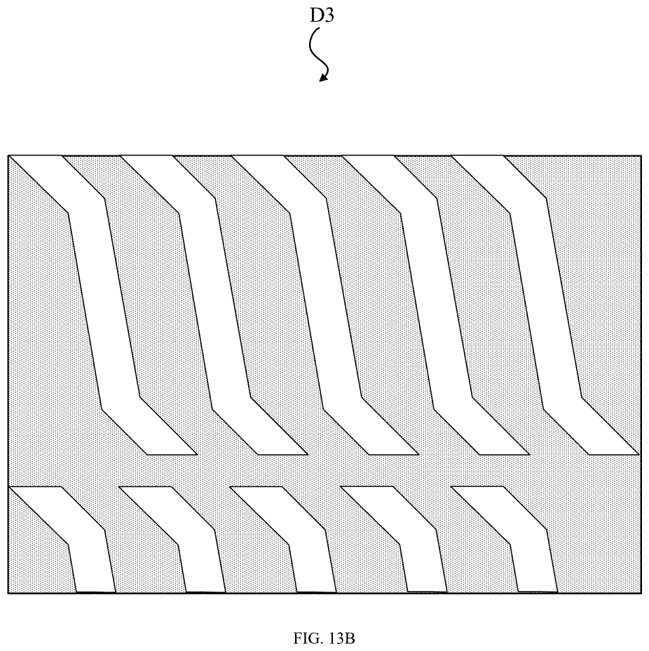

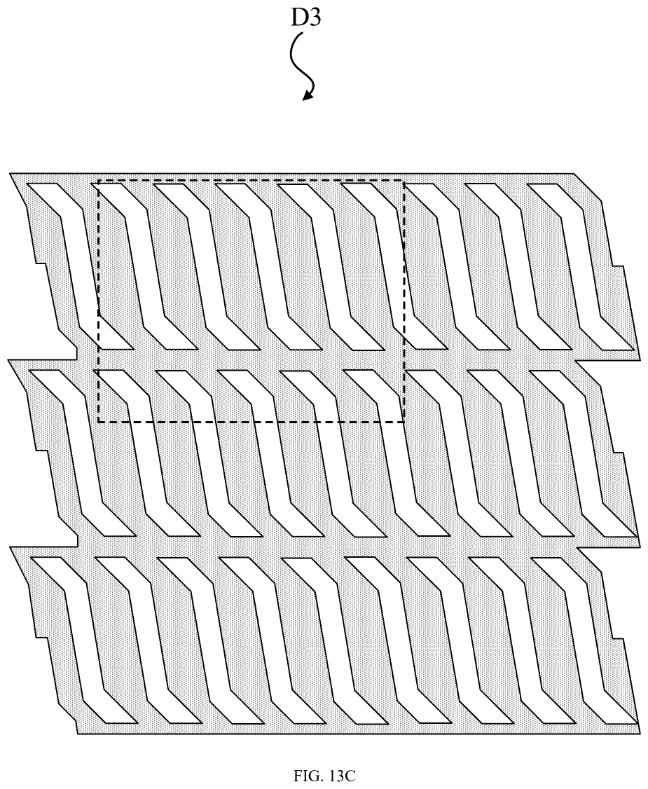

In a possible embodiment, as shown in FIG. 11, FIG. 13A-FIG. 13C, FIG. 13B is the pattern of the third conductive layer corresponding to FIG. 13A, FIG. 13B may also be a local schematic diagram at the dotted line frame in FIG. 13C, that is, FIG. 13C is a schematic diagram of FIG. 13B in a larger range, the array substrate further includes: a third conductive layer D3 located on a side, away from the base substrate, of the second conductive layer D2. The third conductive layer D3 includes a plurality of hollows L, and a part of the orthographic projection of the hollow L on the base substrate 11 overlaps a part of the orthographic projection of the first electrode D21 on base substrate 11, so that a fringe electric field is formed by the first electrode D21 and the third conductive layer D3 at the hollows L. In the embodiment of the disclosure, the array substrate further includes a third conductive layer D3, the third conductive layer D3 includes a plurality of hollows L, and a part of the orthographic projection of the hollow L on the base substrate 11 overlaps a part of the orthographic projection of the first electrode D21 on base substrate 11, so that the first electrode D21 and the third conductive layer D3 may form a fringe field at the hollows L, thereby driving the liquid crystal to deflection. In the embodiment of the present disclosure, the driving mode of the display panel may be a new Fringe Field Switching, FFS or an Advanced Super Dimension Switch, ADS.

It should be noted that in order to clearly illustrate each layer, only the hollow L shape of the third conductive layer D3 is illustrated in FIG. 13A, and the complete pattern of the third conductive layer D3 can be shown in FIG. 13B, and the pattern of the larger region in FIG. 13B can be shown in FIG. 13C.

Specifically, the third conductive layer D3 may be a common electrode layer, which forms an electric field with the first electrode D21, and then drives the liquid crystal molecules between the array substrate and the opposing substrate.

In one possible embodiment, the third conductive layer D3 may includes: a plurality of hollow rows extending along the first direction X and arranged along the second direction Y. Each hollow row includes: a plurality of hollows L arranged sequentially along the first direction X. In one possible embodiment, as shown in FIG. 13A-FIG. 13C, the hollows L may correspond to the first electrodes D21 in one-to-one manner.

In one possible embodiment, a part of the orthographic projection of the hollow L on the base substrate 11 overlaps a part of the orthographic projection of the first metal wire M11 on the base substrate 11. In one possible embodiment, a part of the orthographic projection of the hollow L on the base substrate 11 overlaps a part of the orthographic projection of the third metal wire M31 on the base substrate 11.

In one possible embodiment, the orthographic projection of the second metal wire M21 on the base substrate 11 covers the orthographic projection of the gap between the two adjacent hollow rows on the base substrate 11.

In one possible embodiment, as shown in FIG. 11 and FIG. 12, the array substrate further includes: a fourth metal layer M4 located on a side, facing the base substrate 11, of the third conductive layer D3 and in contact with the third conductive layer D3. The fourth metal layer M4 includes: a plurality of fourth metal wires M41 extending along the first direction X, and the orthographic projection of the fourth metal wires M41 on the base substrate 11 covers the orthographic projection of the first metal wire M11 on the base substrate 11.

Specifically, the conductivity of the fourth metal layer M4 may be better than that of the third conductive layer D3. A plurality of fourth metal wires M41 in contact with the third conductive layer D3 arranged on the array substrate can reduce the resistance of the third conductive layer D3.

In one possible embodiment, as shown in FIG. 11, the display panel may also include at least one of the following: a buffer layer 12 located between the base substrate 11 and the second active layer C2; a second gate insulating layer 13 located between the second active layer C2 and the third metal layer M3; a third interlayer dielectric layer 14 located between the third metal layer M3 and the first active layer C1; a first gate insulating layer 15 located between the first active layer C1 and the second metal layer M2; a first interlayer dielectric layer 16 located between the second metal layer M2 and the first metal layer M1; a second interlayer dielectric layer 17 located between the first metal layer M1 and the first conductive layer D1; a first planarization layer 18 between the first conductive layer D1 and the second conductive layer D2; and a second planarization layer 19 between the second conductive layer D2 and the fourth metal layer M4.

In some examples, at least one of the buffer layer 12, the second gate insulating layer 13, the third interlayer dielectric layer 14, the first gate insulating layer 15, the first interlayer dielectric layer 16, the second interlayer dielectric layer 17, the first planarization layer 18, or the second planarization layer 19 may be an inorganic insulating layer, for example, the materials of which may be any one or more of silica oxide (SiOx), silitride (SiNx), or silicon nitride oxide (SiON), which may be a single layer, multiple layers, or composite layers.

In one possible embodiment, the material of the first active layer C1 includes: a metal oxide doped with rare earth elements. Specifically, the material of the first active layer Cl is a metal oxide semiconductor material, and the metal oxide semiconductor material may include: any one or more of amorphous indium gallium zinc oxide material (a-IGZO), zinc nitride oxide (ZnON), or indium zinc tin oxide (IZTO), indium gallium zinc oxide (IGZO), indium gallium oxide zinc (IGO), indium gallium zinc oxide tin oxide (IGZTO), indium zinc oxide (IZO), rare earth element doped metal oxide (RE-OS). The rare earth element doped metal oxides may include lanthanide doped metal oxides (Ln-OS). The crystalline state of the active layer material can be amorphous, partially crystalline or polycrystalline. In the embodiment of the present disclosure, the material of the first active layer C1 is a metal oxide doped with rare earth elements, and the first active layer C1 can have stable performance even if it is exposed to light, and then the light-shielding layer is not required to be set in the light transmitting region P, and the aperture ratio of the display panel can be further improved. In the embodiment of the present disclosure, the first active layer C1 of the transistor in the display region may adopt an oxide active layer, that is, the thin-film transistor of the oxide active layer has the advantages of low leakage current.

In one possible embodiment, the material of the second active layer C2 includes: low-temperature polysilicon. That is, considering that the current design of the high-migration oxide gate drive circuit is not mature enough, the transistor size in the gate drive circuit is larger, resulting in an excessively large frame. In the embodiment of the present disclosure, a low-temperature polycrystalline silicon transistor design may be adopted in the gate drive circuit in the non-display region.

In the embodiment of the present disclosure, the first active layer C1 of the first transistor in the display region may adopt an oxide active layer, and the second active layer C2 of the second transistor in the non-display region may adopt a polycrystalline silicon active layer, because the oxide thin-film transistor has the advantages such as low leakage current, the low-temperature polycrystalline silicon thin-film transistor has the advantages of high mobility and fast charging, and the low-temperature polycrystalline silicon thin-film transistor and the oxide thin-film transistor are integrated on a display panel to form a low-temperature polycrystalline oxide display panel, and the advantages of both are utilized, which can achieve high resolution (PPI) and low frequency drive, can reduce power consumption, and can improve display quality. For example, the array substrate provided in the embodiment of the present disclosure integrates the technical effects of high mobility and narrow frame of polysilicon material as the second transistor of the second active layer C2, and the display effect of high transmittance of the metal-oxide semiconductor material as the first transistor of the first active layer C1, and the display effect of virtual reality can be further improved when the array substrate is used in the display panel.

In one possible embodiment, the first active layer C1 and the second active layer C2 may also be arranged on the same layer and of same material. Specifically, the first active layer C1 and the second active layer C2 can be oxide active layers, specifically, for example, the materials of the first active layer C1 and the second active layer C2 can include: amorphous indium gallium zinc oxide material (a-IGZO), zinc nitrogen oxide (ZnON), or indium zinc tin oxide (IZTO). In the embodiment of the present disclosure, when an oxide active layer is used for both the active layers of the transistors in the display region and the non-display region, the second transistor in the non-display region, and the first transistor in the display region can adopt an oxide double-gate structure, and the bottom gate size of the second transistor in the non-display region is greater than the top gate size of the second transistor in the non-display region (the unilateral wrapping size may be 0.5 μm to 2 μm), which can effectively improve the on-state current and device stability of the second transistor in the non-display region. For the first transistor in the display region, the bottom gate size can be smaller than the top gate size (the bottom gate is unilaterally reduced by 0.3μm to 0.6μm compared with the top gate), which can avoid the influence on the aperture ratio.

In one possible embodiment, the material of the first conductive layer D1 may include: metal oxides (e.g., indium tin oxide, indium-doped zinc oxide (AZO), fluorine-doped tin oxide (AZO), aluminum-doped zinc oxide (AZO), indium-doped cadmium oxide).

In one possible embodiment, the materials of the second conductive layer D2 may include: metal oxides (e.g., indium tin oxide, indium-doped zinc oxide (AZO), fluorine-doped tin oxide (AZO), aluminum-doped zinc oxide (AZO), indium-doped cadmium oxide).

In one possible embodiment, the materials of the third conductive layer D3 may include: metal oxides (e.g., indium tin oxide, indium-doped zinc oxide (AZO), fluorine-doped tin oxide (AZO), aluminum-doped zinc oxide (AZO), indium-doped cadmium oxide).

In one possible embodiment, the materials of at least two of the first conductive layer D1, the second conductive layer D2, and the third conductive layer D3 are identical. In one possible embodiment, the materials of the first conductive layer D1, the second conductive layer D2, and the third conductive layer D3 may also be different.

In one possible embodiment, the materials of at least one of the first metal layer M1, the second metal layer M2, the third metal layer M3, and the fourth metal layer M4 may include: any one or more of the silver (Ag), copper (Cu), aluminum (Al), titanium (Ti), and molybdenum (Mo), or the alloying material of the above-mentioned metals, such as aluminum neodymium alloy (AINd) or molybdenum-niobium alloy (MoNb), may be a single-layer structure, or a multi-layer composite structure, such as Ti/A1/Ti, etc.

In one possible embodiment, at least two of the first metal layer M1, the second metal layer M2, the third metal layer M3, or the fourth metal layer M4 are of the same material. In one possible embodiment, the materials of the first metal layer M1, the second metal layer M2, the third metal layer M3, and the fourth metal layer M4 may also be different.

In some examples, the base substrate 11 may be a flexible substrate or a rigid substrate. For example, a rigid substrate may include a glass substrate. The flexible substrate may include a first flexible material layer, a first inorganic material layer, a semiconductor layer, a second flexible material layer and a second inorganic material layer which are stacked. The materials of the first flexible material layer and the second flexible material layer may adopt materials such as polyimide (PI), polyethylene terephthalate (PET) or surface-treated polymer soft film. The materials of the first inorganic material layer and the second inorganic material layer may adopt silicon nitride (SiNx) or silicon oxide (SiOx) etc., which are used to improve the water-and-oxygen resistance of the base substrate. The material of the semiconductor layer may be amorphous silicon (a-Si). However, the embodiments of the present disclosure are not limited to this.

Based on the same invention conception, an embodiment of the disclosure also provides a display panel, including an array substrate provided in the embodiment of the present disclosure and an opposing substrate arranged opposite to the array substrate.

In one possible embodiment, the opposing substrate may include an opposing base substrate, a black matrix located on a side of the opposing base substrate, and an optical adhesive layer located on a side, away from the opposing base substrate, of the black matrix.

In one possible embodiment, the display panel further includes: a color film layer. The color layer may be in the opposing substrate, or the color layer may be in the array substrate.

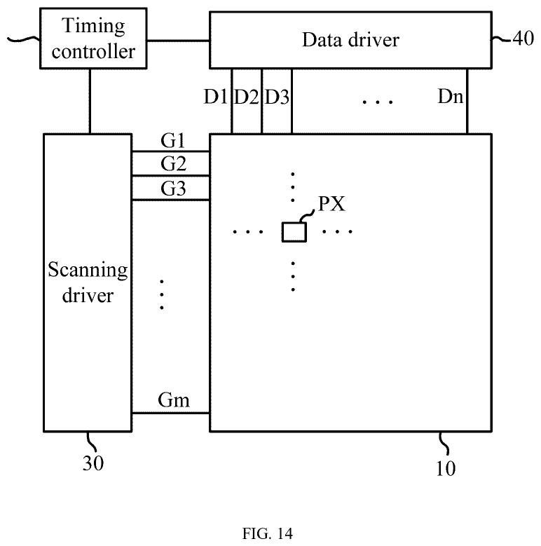

FIG. 14 is a schematic diagram of the structure of the display panel of at least one embodiment of the present disclosure. In some examples, as shown in FIG. 14, the display panel may include: a timing controller 20, a data driver 40, a gate drive circuit, and a subpixel array 10. The gate drive circuit may include at least one driver, for example, including a scanning driver 30. The timing controller 20, the data driver 40 and the gate drive circuit may be located in the non-display region outside the display region of the display panel. The subpixel array 10 located in the display region may include a plurality of subpixels PX arranged in a regular arrangement. The scanning driver 30 may be configured to supply the scanning signal to the subpixels PX along the scan line. The data driver 40 may be configured to supply a data signal to the subpixels PX along the data line. The timing controller 20 can be configured to control the scanning driver 30 and the data driver 40.

In some examples, the timing controller 20 can provide gray values and control signals of specifications suitable for the data driver 40 to the data driver 40. The timing controller 20 can provide the clock signal, the initial signal, etc., of the specifications suitable for the scanning driver 30 to the scanning driver 30. The data driver 40 can utilize the gray values and control signals received from the timing controller 20 to generate a data voltage that is supplied to the data lines D1 to Dn. For example, the data driver 40 can sample the gray values with the clock signal, and apply the data signal corresponding to the gray values to the data line D1 to Dn in subpixel behavior units. The scanning driver 30 can generate a scanning signal that is supplied to the scanning lines G1 to Gm by the clock signal, the initial signal, etc., received from the timing controller 20. For example, the scanning driver 30 can sequentially supply scan signals with an on-level pulse to the scan lines. In some examples, the scanning driver 30 may include a shift register that can sequentially generate scanning signals in the form of an on-level pulse to the next stage circuit under the control of a clock signal. Wherein n and m are natural numbers.

In some examples, the gate drive circuit can be set directly on the base substrate. For example, the gate drivers can be set in the periphery region on the left and right sides of the display region. In some examples, the gate drivers can be formed with the subpixels in the process of forming the subpixels. However, the present embodiment is not limited to the position or formation mode of the gate drivers. In some examples, the gate drivers can be set up on a separate chip or printed circuit board to connect to a pad or pad formed on the base substrate.

In some examples, the data driver 40 can be set up on a separate chip or printed circuit board to be connected to the subpixels PX via a signal access pin set on the base substrate. For example, the data driver 40 can be configured with chip-on-glass, chip-on-plastic, chip-on-film, etc., to connect to a signal access pin on the base substrate. The timing controller 20 can be set separately from the data driver 40 or integrated with the data driver 40. However, this embodiment is not limited to this.

Based on the same invention conception, an embodiment of the present disclosure also provides a display apparatus, which includes a display panel provided in the embodiment of the present disclosure.

In the embodiment of the disclosure, the minimum distance a between the orthographic projection of the conductive portion D11 on the base substrate 11 and the orthographic projection of the first metal sub-wire MA on the base substrate 11 is greater than the minimum distance b between the orthographic projection of the conductive portion D11 on the base substrate 11 and the orthographic projection of the second metal sub-wire MB on the base substrate 11, so that the lateral capacitance between the first metal wire M11 and the conductive portion D11 can be increased, and the second coupling capacitance C_{dp2} can further be increased, and because the overlapping capacitance of the first active pattern C11 and the conductive portion D11 (as shown in the region of the thick solid line frame S in FIG. 5D) accounts for the main portion of the first coupling capacitance C_{dp1}, the distance between the conductive portion D11 and the second metal sub-wire MB decreases, which does not have a great impact on the first coupling capacitance C_{dp1}, thereby reducing the difference between the second coupling capacitance C_{dp2} and the first coupling capacitance C_{dp1}, thereby improving the vertical crosstalk defect.

It should be noted that in the present disclosure, “same layer” refers to a layer structure formed by the same film-forming process to form a layer for making a specific pattern, and then formed by using the same mask plate through a one-time patterning process. That is, a patterning process corresponds to a mask (also known as a photomask). Depending on the particular pattern, a patterning process may include multiple exposures, impressions, or etchings, and the specific patterns in the layer structure can be continuous or discontinuous, and these specific patterns may be at different heights or have different thicknesses.

Although preferred embodiments of the present invention have been described, those embodiments may be subject to additional changes and modifications once the basic inventive concepts are known to those skilled in the art. Therefore, the attached claims are intended to be construed to include the preferred embodiment and all changes and modifications that fall within the scope of the invention.

Obviously, a person skilled in the art may make various changes and variants to the embodiments of the present invention without departing from the spirit and scope of the embodiments of the present invention. Thus, if these modifications and variants of the embodiments of the present invention fall within the scope of the claims of the present invention and their equivalents, the present invention is also intended to include such modifications and variants.

1.-29. (canceled)

30. An array substrate, provided with a display region and a non-display region located at a periphery of the display region, and comprising:
a base substrate;
a first active layer located on a side of the base substrate and comprising a plurality of first active patterns in the display region; wherein each first active pattern comprises: a first portion extending in a first direction, and a second portion extending from one end of the first portion;
a first metal layer comprising a plurality of first metal wires extending in the first direction; wherein an orthographic projection of the first portion on the base substrate is located between orthographic projections of adjacent first metal wires on the base substrate, and a part of an orthographic projection of the second portion on the base substrate overlaps a part of an orthographic projection of the first metal wire on the base substrate;
a first conductive layer comprising a plurality of conductive portions located in the display region; wherein an orthographic projection of at least one of the conductive portions on the base substrate is located between the orthographic projections of adjacent first metal wires on the base substrate; and
a second conductive layer comprising a plurality of first electrodes located in the display region;
wherein a first metal sub-wire and a second metal sub-wire comprised in the first metal wire are on two sides adjacent to the conductive portion; wherein the first metal sub-wire is electrically connected with the second portion; the first portion is electrically connected with the first electrode through the conductive portion; a distance between an orthographic projection of the conductive portion on the base substrate and an orthographic projection of the first metal sub-wire on the base substrate is greater than a distance between the orthographic projection of the conductive portion on the base substrate and an orthographic projection of the second metal sub-wire on the base substrate.

31. The array substrate of claim 30, wherein the conductive portion, the first metal sub-wire and the second metal sub-wire satisfy a following relation:
15%≤b/a≤75%, wherein a represents a minimum distance between the orthographic projection of the conductive portion on the base substrate and the orthographic projection of the first metal sub-wire on the base substrate, and b represents a minimum distance between the orthographic projection of the conductive portion on the base substrate and the orthographic projection of the second metal sub-wire on the base substrate.

32. The array substrate of claim 31, wherein the conductive portion, the first metal sub-wire and the second metal sub-wire satisfy a following relation:
3%≤(a−b)/c≤15%, where c represents a minimum distance between the first metal sub-wire and the second metal sub-wire adjacent to the first metal sub-wire.

33. The array substrate of claim 32, wherein the conductive portion, the first metal sub-wire and the second metal sub-wire satisfy a following relation:
60%≤d/c≤95%, wherein d represents a length of the conductive portion in a direction perpendicular to the first direction.

34. The array substrate of claim 30, wherein the first portion comprises a first symmetry axis extending in the first direction, and the conductive portion comprises a second symmetry axis extending in the first direction; and
the second symmetry axis is located on a side, away from the first metal sub-wire, of the first symmetry axis.

35. The array substrate of claim 30, wherein the first electrode comprises a first outer edge extending in the first direction; between two adjacent first metal wires, a part of an orthographic projection of the first outer edge on the base substrate is located on a side, away from the first metal sub-wire, of the orthographic projection of the first portion on the base substrate;
the conductive portion comprises a second outer edge extending in the first direction;
between two adjacent first metal wires, a part of an orthographic projection of the second outer edge on the base substrate is located on a side, away from the first metal sub-wire, of the orthographic projection of the first portion on the base substrate; and
between two adjacent first metal wires, a part of the orthographic projection of the second outer edge on the base substrate is located on a side, away from the first metal sub-wire, of the first outer edge.

36. The array substrate of claim 35, wherein the first electrode comprises a third outer edge extending in the first direction; between two adjacent first metal wires, a part of an orthographic projection of the third outer edge on the base substrate is located on a side, close to the first metal sub-wire, of the orthographic projection of the first portion on the base substrate;
the conductive portion comprises a fourth outer edge extending in the first direction;
between two adjacent first metal wires, a part of an orthographic projection of the fourth outer edge on the base substrate is located on a side, close to the first metal sub-wire, of the orthographic projection of the first portion on the base substrate; and
between two adjacent first metal wires, a part of the orthographic projection of the fourth outer edge on the base substrate is located on a side, away from the first metal sub-wire, of orthographic projection of the third outer edge on the base substrate.

37. The array substrate of claim 35, wherein the first electrode comprises a third outer edge extending in the first direction; between two adjacent first metal wires, a part of an orthographic projection of the third outer edge on the base substrate is located on a side, close to the first metal sub-wire, of the orthographic projection of the first portion on the base substrate;
the conductive portion comprises a fourth outer edge extending in the first direction;
between two adjacent first metal wires, a part of an orthographic projection of the fourth outer edge on the base substrate is located on a side, close to the first metal sub-wire, of the orthographic projection of the first portion on the base substrate; and
between the two adjacent first metal wires, a part of the orthographic projection of the third outer edge on the base substrate coincides with a part of the orthographic projection of the fourth outer edge on the base substrate.

38. The array substrate of claim 30, further comprising: a second metal layer located between the first active layer and the first conductive layer, wherein the second metal layer comprises a plurality of second metal wires extending in a second direction;
the first portion comprises: a first sub-portion, a second sub-portion, and a third sub-portion that are sequentially distributed along the first direction; wherein an orthographic projection of the second sub-portion on the base substrate overlaps an orthographic projection of the second metal wire on the base substrate; the first sub-portion is located on a side, facing the second portion, of the second sub-portion, and the third sub-portion is located on a side, away from the second portion, of the second sub-portion; and
an orthographic projection of the first sub-portion on the base substrate and the orthographic projection of the conductive portion on base the substrate have an overlapping region.

39. The array substrate of claim 30, further comprising: a second metal layer located between the first active layer and the first conductive layer, wherein the second metal layer comprises a plurality of second metal wires extending in the second direction; the second portion comprises: a fourth sub-portion connected with the first portion and extending in a third direction, and a fifth sub-portion connected with the fourth sub-portion;
the first metal wire is electrically connected with the fifth sub-portion; the second direction intersects with the first direction, and the third direction intersects with the first direction;
the conductive portion comprises: a fifth outer edge extending in the second direction and facing the fifth sub-portion; and
the orthographic projection of the second metal wire on the base substrate covers an orthographic projection of the fifth outer edge on the base substrate.

40. The array substrate of claim 39, wherein a distance between the orthographic projection of a sixth outer edge on the base substrate and the orthographic projection of the fifth outer edge on the base substrate in the first direction is one-fifth to four-fifths of a length of the orthographic projection of the second metal wire in the first direction on the base substrate.

41. The array substrate of claim 39, wherein the second metal wire comprises a sixth outer edge extending in the second direction and facing the fifth sub-portion;
an orthographic projection of the sixth outer edge on the base substrate is located on a side, facing the orthographic projection of the fifth sub-portion on the base substrate, of the orthographic projection of the fifth outer edge on the base substrate.

42. The array substrate of claim 30, wherein the first conductive layer is located on a side, away from the base substrate, of the first active layer;
the array substrate further comprises: a first insulating layer located between the first active layer and the first conductive layer, and a first through hole penetrating through the first insulating layer, wherein the conductive portion is electrically connected with the first portion through the first through hole;
between two adjacent first metal wires, a minimum distance between a center of an orthographic projection of the first through hole on the base substrate and the orthographic projection of the first metal sub-wire on the base substrate is greater than a minimum distance between the center of the orthographic projection of the first through hole on the base substrate and the orthographic projection of the second metal sub-wire on the base substrate.

43. The array substrate of claim 42, wherein the first electrode is located on a side, away from the base substrate, of the first conductive layer;
the array substrate further comprises: a second insulating layer located between the first conductive layer and the first electrode, and a second through hole penetrating through the second insulating layer; the first electrode is electrically connected with the conductive portion through the second through hole; and
between two adjacent first metal wires, a minimum distance between a center of an orthographic projection of the second through hole on the base substrate and the orthographic projection of the first metal sub-wire on the base substrate is greater than a minimum distance between the center of the orthographic projection of the second through hole on the base substrate and the orthographic projection of the second metal sub-wire on the base substrate.

44. The array substrate of claim 43, wherein at least a part of the orthographic projection of the first through hole on the base substrate does not overlap at least a part of the orthographic projection of the second through hole on the base substrate.

45. The array substrate of claim 38, further comprising: a third metal layer located on a side, facing the base substrate, of the first active layer; wherein the third metal layer comprises: a plurality of third metal wires extending in the second direction, and an orthographic projection of the third metal wire on the base substrate covers the orthographic projection of the second metal wire on the base substrate.

46. The array substrate of claim 45, further comprising: a plurality of pixel light transmitting regions, and each pixel light transmitting regions comprises: a plurality of pixel light transmitting region rows extending in the first direction and arranged in the second direction; at least one of the pixel light transmitting region rows comprises: a first pixel light transmitting region, a second pixel light transmitting region, and a third pixel light transmitting region; a waveband range of emergent light of the third pixel light transmitting region is smaller than a waveband range of emergent light of the first pixel light transmitting region, and smaller than a waveband range of emergent light of the second pixel light transmitting region; and
the third metal wire comprises: a third metal wire main portion extending in the second direction, and a first shading structure connected to the third metal wire main portion; a maximum length of the first shading structure in the first direction is greater than a maximum length of the third metal wire main portion in the first direction; an orthographic projection of the first shading structure on the base substrate is located in a gap between orthographic projections of at least two partially adjacent third pixel light transmitting regions in the first direction on the base substrate;
wherein the array substrate comprises a spacer; wherein the orthographic projection of the first shading structure on the base substrate covers an orthographic projection of the spacer on the base substrate.

47. The array substrate of claim 45, wherein the third metal wire further comprises: a second shading structure connected to a third metal wire main portion; a maximum length of the second shading structure in the first direction is greater than the maximum length of the third metal wire main portion in the first direction, and is less than the maximum length of the first shading structure in the first direction; and
the orthographic projection of the second shading structure on the base substrate is located in a gap between orthographic projections of two partially adjacent third pixel light transmitting regions on the base substrate in the second direction, and the orthographic projection of the second shading structure on the base substrate does not overlap the orthographic projection of the first shading structure on the base substrate.

48. The array substrate of claim 30, further comprising: a third conductive layer on a side, away from the base substrate, of the second conductive layer, the third conductive layer comprises a plurality of hollows, and a part of an orthographic projection of the hollow on the base substrate overlaps a part of the orthographic projection of the first electrode on the base substrate.

49. A display panel, comprising the array substrate of claim 30 and an opposing substrate arranged opposite to the array substrate.
